(19) United States
(12) Patent Application Publication
(10) Pub. No.: US 2026/0112420 A1
(43) Pub. Date: Apr. 23, 2026

(54) OPERATING METHODS OF MEMORY SYSTEMS, MEMORY SYSTEMS, MEMORY DEVICES AND STORAGE MEDIA

(71) Applicant: Yangtze Memory Technologies Co., Ltd., Wuhan (CN)

(72) Inventors: Teng Zhou, Wuhan (CN); Leilei Xu, Wuhan (CN); Wenli Gao, Wuhan (CN)

(21) Appl. No.: 19/062,970

(22) Filed: Feb. 25, 2025

(30) Foreign Application Priority Data
Oct. 17, 2024 (CN) 202411455711.8

(51) Int. Cl. G11C 16/26; G11C 16/04

(52) U.S. Cl. CPC G11C 16/26; G11C 16/0483

(57) ABSTRACT

The present disclosure describes operating methods of a memory systems, memory systems, memory devices and storage media. Determination of a read voltage includes: performing a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size; and adjusting the candidate read voltage based on the original data corresponding to the candidate read voltage and the original data respectively corresponding to each of the offset read voltages in the plurality of pairs of offset read voltages.

### CROSS-REFERENCE TO RELATED APPLICATIONS

This application claims priority to and the benefit of Chinese Patent Application 202411455711.8, filed on Oct. 17, 2024, which is hereby incorporated by reference in its entirety.

### TECHNICAL FIELD

The present disclosure relates to the field of memory technologies, and in particular, to operating methods of memory systems, memory systems, memory devices, and storage media.

### BACKGROUND

Memory devices such as NAND have higher requirements on performance and reliability of data error correction, which requires the use of a suitable read voltage during read operation.

During the use of the memory device, in order to maintain reliability of data reading, the memory system may periodically or aperiodically update the read voltage used in the read operation.

### BRIEF DESCRIPTION OF DRAWINGS

In order to more clearly illustrate the technical solutions in the examples of the present disclosure, the accompanying drawings that need to be used in the description of the examples are briefly described below, and it is apparent that the drawings in the following description are merely some examples of the present disclosure, and for those of ordinary skill in the art, other drawings may be obtained based on these drawings without creative work.

FIG. 1 is a schematic diagram of a system according to an example of the present disclosure.

FIG. 2 is a schematic structural diagram of a memory card according to the present disclosure.

FIG. 3 is a schematic structural diagram of a solid state drive according to the present disclosure.

FIG. 4 is a block diagram of a memory device according to an example of the present disclosure.

FIG. 5 is a schematic circuit diagram of a memory device according to an example of the present disclosure.

FIG. 6 is a cross-sectional side view of a memory string according to an example of the present disclosure.

FIG. 7 is a schematic diagram of threshold voltage distribution of a TLC according to the present disclosure.

FIG. 8 is a diagram of a relationship between a voltage and a number of flipped bits according to the present disclosure.

FIG. 9 is another diagram of a relationship between a voltage and a number of flipped bits according to the present disclosure.

FIG. 10 is a flowchart of an operating method of a memory system according to an example of the present disclosure.

FIG. 11 is a diagram of a relationship between a voltage and a number of flipped bits according to an example of the present disclosure.

FIG. 12 is a flowchart of an operating method of a memory system according to another example of the present disclosure.

FIG. 13 is a diagram of a relationship between a voltage and a number of flipped bits according to an example of the present disclosure.

FIG. 14 is a schematic diagram of calculating a composite flip count difference according to an example of the present disclosure.

FIG. 15 is another schematic diagram of calculating a composite flip count difference according to an example of the present disclosure.

FIG. 16 is a schematic flowchart of determining a read voltage in an iterative manner according to an example of the present disclosure.

FIG. 17 is a schematic flowchart of data reading according to an example of the present disclosure.

### DETAILED DESCRIPTION

The examples of the present disclosure are described in detail below with reference to the accompanying drawings.

The system provided in the examples of the present disclosure may comprise a host and a memory system. The memory system may comprise a 3D memory device, for example, may be a 3D NAND flash.

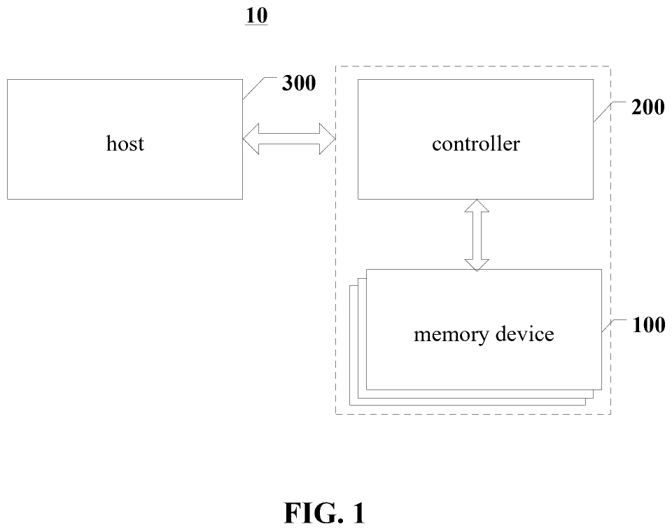

FIG. 1 is a schematic diagram of a system according to an example of the present disclosure. As shown in FIG. 1, the computer system 10 comprises one or more memory devices 100, and a controller 200 coupled to the memory device 100 and configured to control the memory device 100. The controller 200 may also be referred to as a memory controller.

The controller 200 may be configured to control operations performed by the memory device 100, for example, read, erase, and program operations. The controller 200 may also be configured to manage various functions regarding data stored in or to be stored in the memory device 100, comprising, but not limited to, bad block management, garbage collection, translation of logical addresses to physical addresses, wear leveling, and the like. Optionally, the controller 200 may be further configured to process Error Correcting Code (ECC) regarding data read from or written to the memory device 100. The controller 200 may also perform any other suitable functions, for example, formatting the memory device 100.

The controller 200 may also communicate with external devices according to a particular communication protocol. For example, the controller 200 may communicate with the external devices through at least one of various interface protocols. The interface protocol may be a Universal Serial Bus (USB) protocol, a Multi-Media Card (MMC) protocol, a Peripheral Component Interconnect (PCI) protocol, a PCI Express (PCI-E) protocol, an Advanced Technology Attachment (ATA) protocol, a serial ATA protocol, a parallel ATA protocol, a Small Computer System Interface (SCSI) protocol, an Enhanced Small Drive Interface (ESDI) protocol, an Integrated Development Environment (IDE) protocol, a Fire wire protocol, and the like.

In an optional example, the controller 200 and the one or more memory devices 100 may be integrated into various types of electronic devices. The electronic device may be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory therein. In this scenario, as shown in FIG. 1, the computer system 10 further comprises a host 300. The controller 200 is coupled to the host 300. The controller 200 may manage data stored in the memory device 100 and communicate with the host 300 to implement the functions of the foregoing electronic device.

In other examples, the controller 200 and the one or more memory devices 100 may be integrated into various types of storage devices.

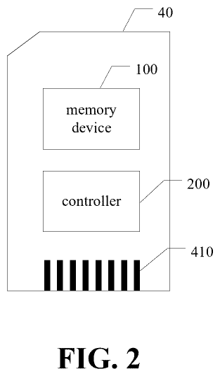

As an example, FIG. 2 is a schematic structural diagram of a memory card according to the present disclosure. As shown in FIG. 2, the controller 200 and the single memory device 100 may be integrated into the memory card 40. The memory card 40 may comprise a personal computer memory card international association (PCMCIA, PC) card, a compact flash (CF) card, a smart media (SM) card, a memory stick, a multimedia card (MMC), an reduced small MMC (RS-MMC), a micro-MMC, a secure digital (SD) card, a universal flash storage (UFS), or the like. As shown in FIG. 2, the memory card 40 may also comprise a connector 410 that couples the memory card 40 with the host.

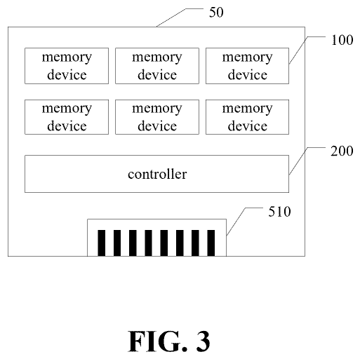

As another example, FIG. 3 is a schematic structural diagram of a solid state drive according to the present disclosure. As shown in FIG. 3, the controller 200 and the plurality of memory devices 100 may be integrated into a Solid State Disk (SSD) 50. The solid state drive 50 may also comprise a connector 510 that couples the solid state drive 50 with the host. A storage capacity and/or an operating speed of the solid state drive 50 is greater than a storage capacity and/or an operating speed of the memory card 40.

In addition, the memory device 100 in FIG. 1 to FIG. 3 may be any memory device according to an example of the present disclosure, for example, a 3D NAND memory device. The structure of the memory device 100 is explained below.

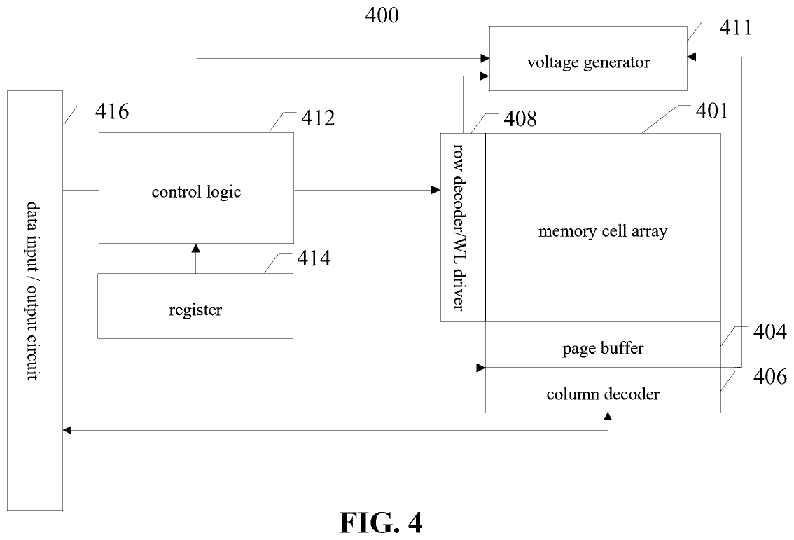

FIG. 4 is a block diagram of a memory device according to an example of the present disclosure. Referring to FIG. 4, the memory device 400 may comprise a memory cell array 401, a page buffer 404, a column decoder 406, a row decoder/word line (WL) driver 408, a voltage generator 411, a control logic 412, a register 414, and a data input/output circuit 416. It should be understood that in some examples, additional peripheral circuits not shown in FIG. 4 may also be included.

The page buffer 404 may be configured to read data from and program (write) data to the memory cell array 401 according to control signals from the control logic 412. In one example, the page buffer 404 may store data (write data) to be programmed into a selected page of the memory cell array 401. In another example, the page buffer 404 may output the read data in a program verify operation to ensure that the data has been properly programmed into a corresponding memory cell coupled to a selected word line of the memory cell array 401. Column decoder 406 may operate in response to control signals provided by the control logic unit to select one or more NAND memory strings in the memory cell array 401. The row decoder may operate in response to control signals provided by the control logic unit and select/deselect a selected row of the memory cell array 401. The row decoder may also be configured to supply a voltage generated from the voltage generator 411 to a select word line and an unselected word line of the memory cell array 401. As described in detail below, row decoder/word line driver 408 is configured to perform an erase operation on memory cells coupled to one or more selected word lines in memory cell array 401. The voltage generator 411 may use an external supply voltage or an internal supply voltage to generate various voltages required for the memory device, such as program voltage, read voltage, pass voltage, verify voltage, bit line voltage, etc., and combinations thereof.

The control logic 412 may be coupled to the voltage generator 411, the page buffer 404, the column decoder 406, the row decoder/word line driver 408, and the data input/output circuit 416, etc., and configured to control operation of the various peripheral circuits. The control logic unit may generate an operating signal in response to a command or control signal from the memory controller. Registers 414 may be coupled to control logic 412 and comprise status registers, command registers, and address registers for storing status information, command operation codes (OP codes), and command addresses for controlling operation of each peripheral circuit. The data input/output circuit 416 may be coupled to the control logic 412 and act as a control buffer to buffer control commands received from the host (not shown) and relay it to the control logic 412 and buffer status information received from the control logic 412 and relay it to the host. The data input/output circuit 416 may also be coupled to a column decoder and act as a data input/output interface and a data buffer to buffer data and relay it to the memory cell array 401 or buffer or relay data from the memory cell array 401.

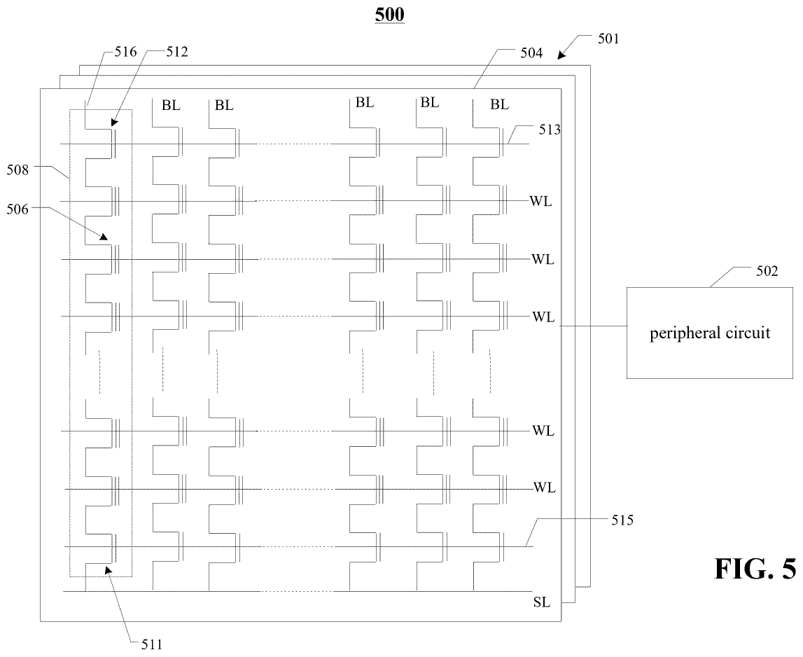

FIG. 5 is a schematic circuit diagram of a memory device according to an example of the present disclosure. As shown in FIG. 5, the memory device 500 may comprise a memory cell array device 501 and a peripheral circuit 502 coupled to the memory cell array device 501. The memory cell array device 501 may be an array of NAND flash memory cells, where the memory cells 506 are provided in the form of an array of NAND memory strings 508, each extending vertically above a substrate (not shown). In some implementations, each NAND memory string 508 comprises a plurality of memory cells 506 coupled in series and stacked vertically. Each memory cell 506 may be a floating gate type memory cell comprising a floating gate transistor, or a charge trapping type memory cell comprising a charge trapping transistor. In some implementations, each memory cell 506 is a single-level cell (SLC) that has two possible memory states (or memory states) and can store one bit of data. For example, the first memory state “0” may correspond to a first voltage range and the second memory state “1” may correspond to a second voltage range. In some implementations, each memory cell 506 is a multi-level cell capable of storing more than a single bit of data in more than two memory states. For example, it may be two bits per cell (e.g., multi-level cell (MLC)), three bits per cell (e.g., triple-level cell (TLC)), or four bits per cell (e.g., Quad-Level Cell (QLC)).

As shown in FIG. 5, each NAND memory string 508 may comprise at least one source select transistor 511 at its source terminal and at least one drain select transistor 512 at its drain terminal. The source select transistor 511 and the drain select transistor 512 may be configured to activate the selected NAND memory string 508 during read and program operations. In some implementations, the sources of NAND memory strings 508 in the same block 504 are coupled through the same source line (SL). According to some implementations, a drain select transistor 512 of each NAND memory string 508 is coupled to a respective bit line 516. In some implementations, each NAND memory string 508 is configured to be selected or deselected by applying a select voltage or deselect voltage (e.g., 0V) to a respective drain select transistor 512 via one or more drain select lines 513 and/or by applying a select voltage or deselect voltage (e.g., 0V) to a respective source select transistor 511 via one or more source select lines 515.

As shown in FIG. 5, an array of memory cells may comprise a plurality of blocks. In some implementations, each block 504 is a basic unit of data for an erase operation, e.g., all memory cells 506 on the same block 504 are erased simultaneously.

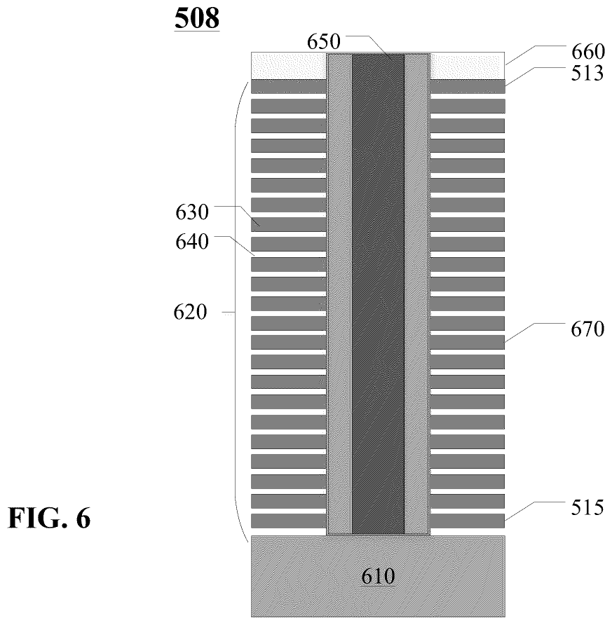

FIG. 6 is a cross-sectional side view of a memory string according to an example of the present disclosure. Referring to FIG. 6, the memory string 508 may extend vertically through the memory cell stack layer 620 over the doped semiconductor layer 610. The doped semiconductor layer 610 is coupled to a source line. In some implementations, the doped semiconductor layer 610 is an N-type doped semiconductor layer. In some other implementations, the doped semiconductor layer 610 is a P-type doped semiconductor layer, where the doped semiconductor layer 610 is a P-well in the substrate, and the substrate is a P-type substrate.

The memory cell stack layer 620 comprises alternating gate conductive layers 630 and gate to gate dielectric layers 640. The number of pairs of the gate conductive layer 630 and the gate to gate dielectric layer 640 in the memory cell stack layer 620 may determine the number of memory cells in the memory array. The gate conductive layer 630 may comprise a conductive material, the conductive material comprises, but not limited to, tungsten (W), cobalt (Co), copper (Cu), aluminum (Al), polysilicon, doped silicon, silicide, or any combination thereof. In a possible implementation, each gate conductive layers 630 comprises a metal layer, for example, a tungsten layer. In some implementations, each gate conductive layer 630 comprises a doped polysilicon layer. Each gate conductive layer 630 may comprise a gate surrounding a memory cell, and may extend laterally as a drain select line (DSL) 513 at the top of the memory cell stack layer 620, laterally as a source select line (SSL) 515 at the bottom of the memory cell stack layer 620, or laterally as a word line (WL) 670 between DSL and SSL.

As shown in FIG. 6, the memory string 508 further comprises a channel structure 650 vertically extending through the memory cell stack layer 620, and the channel structure 650 comprises a channel hole filled with at least one semiconductor material, such as a semiconductor channel, and at least one dielectric material, such as a memory film. In some implementations, the semiconductor channel comprises silicon (e.g., a memory film). In some implementations, the memory film is a composite dielectric layer comprising a tunnel layer, a trap layer, and a block layer. The channel structure 650 may have a cylindrical shape, such as a pillar shape. According to some implementations, a semiconductor channel, a trap layer (also referred to as a memory layer), and a block layer are arranged radially from the center of the pillar toward the outer surface of the pillar in this order. The tunnel layer may comprise silicon oxide, silicon oxynitride, or any combination thereof. The trap layer may comprise silicon nitride, silicon oxynitride, or any combination thereof. The block layer may comprise silicon oxide, silicon oxynitride, a high dielectric constant (high-k) dielectric, or any combination thereof. In one example, the memory film may comprise a composite layer of silicon oxide/silicon oxynitride/silicon oxide.

As shown in FIG. 6, the doped semiconductor layer 660 is stacked on top of the memory cell stack layer 620 in the memory string 508, the doped semiconductor layer 660 is also referred to as a bit line contact, the doped semiconductor layer 660 is coupled to the bit line for connection, and the doped semiconductor layer 660 is an N-type doped semiconductor layer.

When the doped semiconductor layer 660 is an N-type doped semiconductor layer, the memory string 508 may be erased in Gate-Induced Drain Leakage (GIDL) erase manner by a bit line coupled to the doped semiconductor layer 660 and a DSL coupled to the TSG in the memory string 508. For example, an erase voltage is applied to the bit line coupled to the doped semiconductor layer 660, so that the erase voltage acts on the doped semiconductor layer 660, and a voltage less than the erase voltage is applied to the DSL coupled to the TSG in the memory string 508, so that a voltage difference is formed between the gate of the TSG and the doped semiconductor layer 660, and the voltage difference causes a band-to-band tunneling to occur at a position between the gate of the TSG and the doped semiconductor layer 660, and generates GIDL, and a hole in the GIDL moves from the position to the channel of the memory string 508, thereby injecting holes into the channel of the memory string 508 from the position, so that the potential of the channel increases. A voltage (referred to as low voltage, such as 0V) less than the erase voltage is applied to the word line coupled to each memory cell in the memory string 508, so as to apply a low voltage to the gate of the memory cell, and as the channel potential of the memory cell increases, when the voltage difference between the gate of the memory cell and the channel of the memory cell increases, when the voltage difference is greater than the tunneling voltage of the memory cell, the voltage difference causes a tunneling effect between the channel of the memory cell and the gate of the memory cell, and then the hole in the channel of the memory cell is tunneled to the memory layer of the memory cell, so as to eliminate electrons in the memory cell, thereby erasing the memory cell.

In some examples, when the doped semiconductor layer 610 is an N-type doped semiconductor layer, the substring block may be erased in a GIDL erase manner by the source line coupled to the doped semiconductor layer 610 and the SSL coupled to the BSG in the memory string 508. For example, an erase voltage is applied to the source line, and a voltage (referred to as a low voltage) less than the erase voltage is applied to the SSL coupled to the BSG, so that GIDL is generated at a position between the gate of the BSG and the doped semiconductor layer 610, and holes in the GIDL move toward the channel, thereby injecting holes into the channel of the memory string 508 from the position, so that the potential of the channel is increased, a low voltage is applied to the word line coupled to each memory cell in the memory string 508, and as the channel potential of the memory cell increases, when the voltage difference between the gate of the memory cell and the channel of the memory cell is greater than the tunneling voltage of the memory cell, holes in the channel tunnel to the memory layer of the memory cell to eliminate electrons in the memory layer, thereby erasing the memory cell.

Based on this, when both the doped semiconductor layer 610 and the doped semiconductor layer 610 are N-type doped semiconductor layers, the peripheral circuit may perform an erase operation on the memory string 508 in a GIDL erase manner at any end of the memory string 508 (that is, a single-end GIDL erase manner), or may perform an erase operation on the memory string 508 in a GIDL erase manner at two ends of the memory string 508 (that is, a double-end GIDL erase manner).

In some other examples, i when the doped semiconductor layer 610 is a P-type doped semiconductor layer, the memory string 508 is erased based on an erase manner of the P-type doped semiconductor layer. For example, an erase voltage is applied to the source line to apply the erase voltage to the P-type doped semiconductor layer, the erase voltage causes the P-type doped semiconductor layer to generate a hole, a low voltage is applied to the BSG of the memory string 508 and the word line coupled to each memory cell, so that the low voltage acts on the gate of the BSG and the gate of each memory cell, since the low voltage is less than the erase voltage, the hole moves from the P-type doped semiconductor layer to the channel of the memory string 508, so as to inject holes into the channel from the P-type doped semiconductor layer, so that the potential of the channel increases, and as the channel potential of the memory cell increases, when the voltage difference between the gate of the memory cell and the channel of the memory cell is greater than the tunneling voltage of the memory cell, the holes in the channel tunnel to the memory layer of the memory cell, so as to eliminate the electrons in the memory layer, thereby erasing the memory cell.

Based on this, when the doped semiconductor layer 660 is an N-type doped semiconductor layer, the doped semiconductor layer 610 is a P-type doped semiconductor layer, double-end erase can be performed on the memory string 508, for example, a single-end GIDL erase is performed on one end of the memory string 508 close to the N-type doped semiconductor layer, and an erase based on the P-type doped semiconductor layer is performed at the other end of the memory string 508. Or, a single-end GIDL erase is performed on the memory string 508, for example, a single-end GIDL erase is performed on one end of the memory string 508 close to the P-type doped semiconductor layer, and an erase based on the P-type doped semiconductor layer is not performed at the other end of the memory string 508, or a single-end GIDL erase is not performed on one end of the memory string 508 close to the P-type doped semiconductor layer, and an erase based on the P-type doped semiconductor layer is performed at the other end of the memory string 508.

For technical details that are not disclosed in the foregoing memory device related hardware examples, refer to the descriptions of the computer system examples and the method examples of the present disclosure.

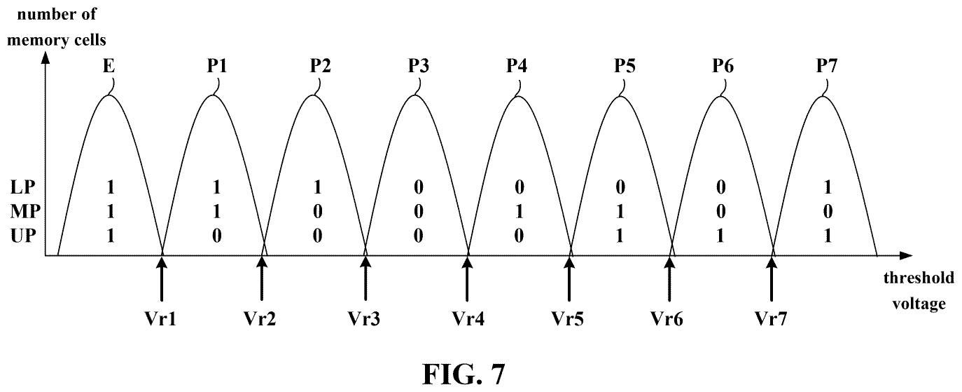

In some examples, a memory cell in a memory device, such as NAND, may have a plurality of memory states corresponding to a plurality of threshold voltage (Vt) distributions, the memory states are also referred to as Vt states. Take TLC as an example, referring to FIG. 7, FIG. 7 shows a schematic diagram of threshold voltage distribution of a TLC according to the present disclosure. The memory states of each memory cell in the TLC respectively comprise an erase state (an E state for short) and 7 program states of P1 to P7 in the order of Vt from low to high, which respectively correspond to the 7 distribution curves in FIG. 7; wherein in the coordinate system in FIG. 7, the abscissa is the threshold voltage, and the ordinate is the number of memory cells. Specifically, each curve in FIG. 7 corresponds to one memory state, and the range of the abscissa corresponding to each curve represents the threshold voltage distribution range corresponding to the memory state; in the above erase state and the 7 program states, it is required to set 7 read voltages (also referred to as comparison voltages) accordingly, which respectively correspond to Vr1 to Vr7 in FIG. 7, wherein the read voltage is used to compare with the threshold voltage of the memory cell in the read operation to distinguish the memory state of the memory cell. Each memory cell in the TLC may store 3 bits, belonging to upper page (UP), middle page (MP), and lower page (LP) respectively; optionally, bit corresponding to each memory state is encoded with Gray code. For example, as shown in FIG. 7, the Gray code of the bit corresponding to the E state is 111, and the Gray code of the bit corresponding to the P1 state is 110, and so on; when the read operation is performed on the memory cell in the TLC, all the data of the three pages of the memory cell may be read out by 7 comparison. In order to balance the read delay and the read interference between the pages, the TLC may use the read manner of 2-3-2, that is, when 7 comparisons are allocated: the LP uses two read voltages (for example, Vr1 and Vr5 in FIG. 7), and the threshold voltage of one memory cell is respectively compared with the two read voltages once (that is, two comparisons), then the bit value of the LP of the memory cell can be determined; the MP uses three read voltages (for example, Vr2, Vr4, and Vr6 in FIG. 7), and the threshold voltage of one memory cell is respectively compared with the three read voltages once (that is, three comparisons), then the bit value of the MP of the memory cell can be determined; and the UP uses two read voltages (for example, Vr3 and Vr7 in FIG. 7), and the threshold voltage of one memory cell is respectively compared with the two read voltages once (that is, two comparisons), then the bit value of the UP of the memory cell can be determined.

For a memory device, during a read operation, the original bit error rate usually changes in fluctuation with the change of the read voltage. The original bit error rate refers to a proportion of error bits in the read original data bits; herein, the original data bits refer to data bits that are read from the memory device and have not been decoded. For example, in FIG. 7, when the read voltage used changes, the original data read from each memory cell also changes, and accordingly, the original bit error rate also changes in fluctuation, wherein the read voltage with the lowest original bit error rate may be referred to as the optimal read voltage.

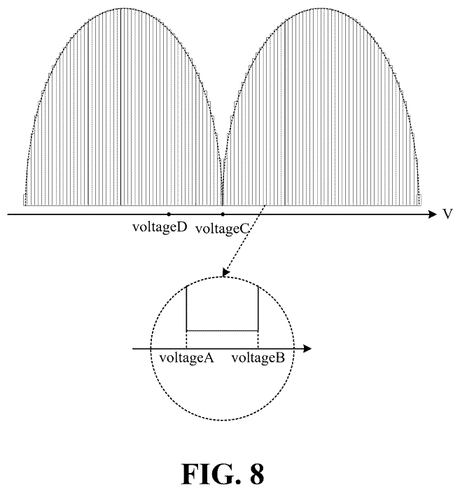

Specifically, for example, referring to FIG. 8, FIG. 8 shows a diagram of a relationship between a voltage and a number of flipped bits according to the present disclosure. In FIG. 8, the abscissa is the read voltage, the width of each pillar is a read voltage span, and the area of the pillar is the number of flipped bits in the read original data under the read voltage span.

For example, as shown in FIG. 8, taking a certain pillar as an example, a read voltage span of the pillar is a voltage A to a voltage B, where a read operation is performed on the memory device by using the voltage A as a read voltage, original data 1 of a specified length may be read from the memory device, the original data 1 is a bit sequence that is not decoded, and a value of each bit in the bit sequence is 0 or 1; a read operation is performed on the memory device by using the voltage B as a read voltage, original data 2 of a specified length may be read from the memory device, the original data 2 is also a bit sequence that is not decoded, a value of each bit in the bit sequence is 0 or 1, and the original data 1 and the original data 2 are compared bit by bit, where a number of bits whose value change (flip bits) is the area of the pillar.

As can be seen from FIG. 8, with the change of the read voltage, the number of flipped bits under each read voltage span changes in fluctuation, and correspondingly, the read voltage corresponding to the valley position (e.g., the voltage C in FIG. 8) can be considered as the optimal read voltage of the memory device.

In some solutions, in the process of searching the optimal read voltage of the memory device, the memory system may find the optimal read voltage in a sequential reading manner, where the sequential reading manner may be as follows: starting from a certain initial read voltage, performing a read operation in sequence according to a certain offset voltage to read the original data from the memory device; and after the original data is read each time, comparing the original data with the previously read original data, determining the flipped bit data, and finding the optimal read voltage by determining a change trend of the number of flipped bits for multiple times.

Taking FIG. 8 as an example, it is assumed that the initial read voltage is the voltage D, the offset direction is the right offset, the memory system first performs the read operation with the voltage D as the read voltage, then the read voltage is sequentially offset from the voltage D to the right, each time the offset value is one offset voltage, after the read operation is performed each time according to the offset read voltage, the number of flipped bits between the original data of the current read operation and the original data of the previous read operation is determined, and whether the change trend of the number of bits is turned is checked; for example, in FIG. 8, the number of flipped bits corresponding to each read operation from the voltage D to the voltage C is gradually decreased, and the number of flipped bits when the read operation is performed with the next read voltage of the voltage C is increased compared to the number of flipped bits when the read operation is performed with the voltage C. In this case, the memory system can determine that the read voltage (e.g., the voltage C) proceeding to the current read voltage is the optimal read voltage.

However, there may be some noise in the memory device, such as random telegraph noise (RTN), which may cause a sudden change in the change trend of the number of flipped bits at the non-valley position under some of read voltage spans.

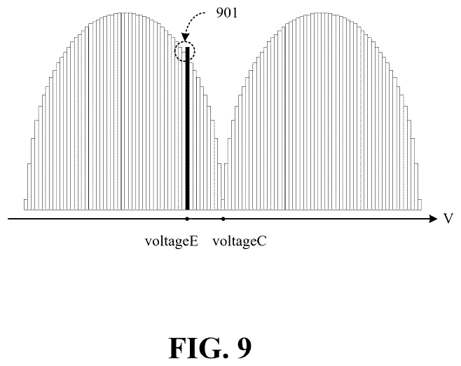

For example, referring to FIG. 9, FIG. 9 shows another diagram of a relationship between a voltage and a number of flipped bits according to the present disclosure. As shown in FIG. 9, the abscissa is the read voltage, the width of each pillar is a read voltage span, and the area of the pillar is the number of flipped bits in the read original data under the read voltage span. Referring to the example in the dashed box 901 in FIG. 9, the read voltage at the valley position is the voltage C, and at the voltage E, the number of flipped bits in one read voltage span after the voltage E increases due to the interference of noise, exceeding the number of flipped bits in one read voltage span before the voltage E; when the optimal read voltage is searched in the sequential reading manner, if the memory system starts to perform the read operation from an initial read voltage on the left side of the voltage E, the number of flipped bits during the read operation decreases successively before the voltage E, and rises in one read voltage span after the voltage E, then the memory system may erroneously determine the voltage E as the optimal read voltage.

For the above problems, the solution shown in the subsequent examples of the present disclosure provides an operating method of a memory system, which can reduce the interference of noise in the process of determining the optimal read voltage of the memory device, and improve the accuracy of finding the optimal read voltage of the memory device.

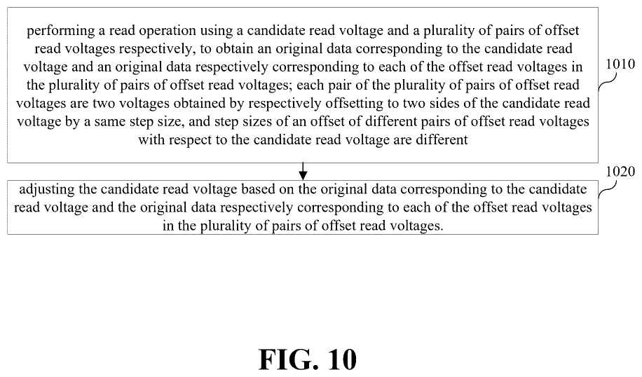

Referring to FIG. 10, FIG. 10 is a flowchart of an operating method of a memory system according to an example of the present disclosure. The method may be performed by a memory system. The memory system may comprises a controller and a memory device, and the method may be performed by a controller in the memory system, or may be performed by a memory device in the memory system, or may be interactively performed by a controller and a memory device in the memory system. As shown in FIG. 10, the method may comprise the following operations.

Operation 1010: perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different.

The original data is a bit sequence that is read from a memory device and has not been decoded.

According to the solution shown in the example of the present disclosure, the read voltage of the memory device can be searched in a multi-round iteration manner. In each round of iteration process, in addition to the candidate read voltage of the current round, a plurality of pairs of offset read voltages are additionally determined, specifically, each pair of offset read voltages are two voltages obtained by respectively offsetting to the left side and the right side of the candidate read voltage by the same step size (which can also be referred to as an offset voltage); and in each round of iteration, the memory system performs a read operation by the candidate read voltage of the current round and the plurality of pairs of offset read voltages (that is, at least 5 read voltages) to obtain the original data respectively corresponding to the at least 5 read voltages.

In a possible implementation, an offset value between two adjacent read voltages in the candidate read voltage and the plurality of pairs of offset read voltages may be the same or different.

In a possible implementation, the offset value between the offset read voltage and the candidate read voltage may be an integer times of a basic offset value.

The basic offset value is a preset voltage offset value. In the process of determining the read voltage, the offset value of different pairs of offset read voltages with respect to the candidate read voltage may be an integer times of the voltage offset value.

For example, assuming that the base offset value is V_{base}, the plurality of pairs of offset read voltages are two pairs of offset read voltages, an absolute value of an offset value between one pair of offset read voltages and the candidate read voltages is V_{base}, that is, one time the basic offset value, and an absolute value of an offset value between the other pair of offset read voltages and the candidate read voltages is 2V_{base}, that is, two times the basic offset value; optionally, if there are also a third pair of offset read voltages, an absolute value of an offset value between the third pair of offset read voltages and the candidate read voltages may be 3V base, that is, three times the basic offset value.

Performing the read operation using the candidate read voltage and the plurality of pairs of offset read voltages respectively may refer to performing the read operation on one or a group of memory cells in the memory device by using the candidate read voltage and the plurality of pairs of offset read voltages to obtain the original data in the one or group of memory cells.

In some examples, the original data may be obtained by performing a read operation in the memory device by using a Single Level Read (SLR) mode.

The SLR mode refers to a mode in which a memory system performs data reading by using a single read voltage in all read voltages corresponding to a certain memory page when reading data in the memory page. For example, taking the threshold voltage distribution of the TLC shown in FIG. 7 as an example, wherein the two read voltages corresponding to the LP are Vr1 and Vr5, and in the process of performing read operation on the LP by the memory system, if the data in the LP needs to be read out accurately, Vr1 and Vr5 need to be used at the same time to perform the read operation. Specifically, when reading the data belonging to the LP in a certain memory cell, the Vr1 and the Vr5 are used to respectively perform a voltage comparison once; and in the example of the present disclosure, since the purpose of data reading is to determine the change of the number of flipped bits in a certain read voltage span without obtaining an accurate data bit, therefore, by using the SLR mode, only the candidate read voltage or the offset read voltage corresponding to the optimal read voltage to be updated is read; for example, still taking the threshold voltage distribution of the TLC shown in FIG. 7 as an example, assuming that the optimal read voltage of Vr1 needs to be determined again, the memory system may read the original data in the LP by using the SLR mode. Specifically, the read operation is performed respectively by using the candidate read voltage and the plurality of pairs of offset read voltages corresponding to Vr1, and it is not required to perform the read operation by using Vr5, that is, in the read operation process on the LP of one memory cell, only one candidate read voltage or one offset read voltage is used to perform the voltage comparison, then the original data required to subsequently determine the optimal read voltage may be obtained.

It can be seen from the above analysis that, when a read operation is performed on a certain memory page through the SLR mode, only a single read voltage is needed to read the original data required to subsequently determine the optimal read voltage, so that the read operation process can be simplified, the efficiency of determining the optimal read voltage is improved, and the resources consumed by determining the optimal read voltage are reduced.

Alternatively, the original data may also be obtained by reading the memory device in other modes other than the SLR mode.

Operation 1020: adjust the candidate read voltage based on the original data corresponding to the candidate read voltage and the original data respectively corresponding to each of the offset read voltages in the plurality of pairs of offset read voltages.

In the examples of the present disclosure, the memory system may determine whether the current candidate read voltage is an optimal read voltage of the memory device according to the original data respectively corresponding to the at least 5 read voltages, and if it is determined that the current candidate read voltage is not an optimal read voltage of the memory device, the memory system may further adjust the candidate read voltage according to the original data respectively corresponding to the at least 5 read voltages, for example, the memory system may determine the adjustment direction and the adjustment step size for the candidate read voltage according to the original data respectively corresponding to the at least 5 read voltages, and adjust the candidate read voltage according to the determined adjustment direction and the adjustment operation, and the adjusted candidate read voltage may be used as the candidate read voltage in the next round of iteration process.

In the foregoing operations, since the memory system may find the optimal read voltage through the original data corresponding to the at least 5 read voltages in each round of iteration, that is, the memory system can identify the change trend of the number of flipped bits in the read voltage span corresponding to the at least 5 read voltages, and determine whether to adjust the candidate read voltage to enter the next round of iteration process according to the change trend of the number of flipped bits in the read voltage span corresponding to the at least 5 read voltages, and adjust the candidate read voltage when determining to enter the next round of iteration process.

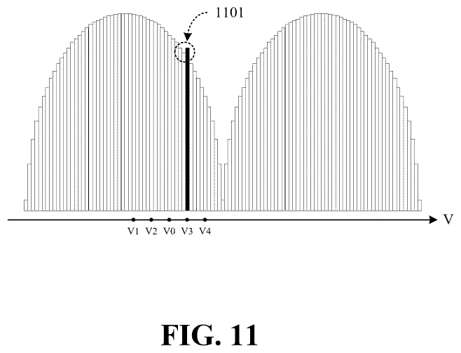

Referring to FIG. 11, FIG. 11 shows a diagram of a relationship between a voltage and a number of flipped bits according to an example of the present disclosure. As shown in FIG. 11, in a round of iteration process, the candidate read voltage is V0, and the plurality of pairs of offset read voltages are V1, V2, V3 and V4, respectively, where V1 and V2 are located on the left side of V0, V3 and V4 are located on the right side of V0, the memory system performs a read operation on the memory device according to V0 to V4 to obtain an original data corresponding to V0 to V4 respectively, through the original data respectively corresponding to V0 to V4, the trend of the number of flipped bits, which changes with the voltage, between V0 to V4 can be analyzed; in particular, on one hand, referring to the example at dashed box 1101 in FIG. 11, although the trend of the number of flipped bits changing with the voltage suddenly changes within a small range due to the noise influence at V3, in the entire read voltage span of V0 to V4, the change trend of the number of flipped bits is substantially downward, so that the noise influence at V3 position can be eliminated; on the other hand, according to the change trend (downward) of the number of flipped bits in the entire read voltage span of V0 to V4, the memory system can determine that the optimal read voltage is on the right side of the current read voltage. In this case, the current read voltage can be adjusted to the right and the memory system enters the next round of iteration process.

In conclusion, the solution according to the examples of the present disclosure provides a solution for searching the optimal read voltage of the memory device in one or more rounds of iteration, where in each round of iteration process, in addition to reading the original data in the memory device by the current candidate read voltage, a plurality of pairs of offset read voltages on two sides of the candidate read voltage are determined, the offset values of two offset read voltages of each pair of offset read voltages with respect to the candidate read voltage are the same and the offset directions of two offset read voltages of each pair of offset read voltages with respect to the candidate read voltage are different, the original data in the memory device is read by the plurality of pairs of offset read voltages, then the original data corresponding to the candidate read voltage and the original data corresponding to the plurality of pairs of offset read voltages are combined, the adjustment manner of the candidate read voltage is integrated, for example, the original data corresponding to the candidate read voltage and the original data respectively corresponding to the plurality of pairs of offset read voltages are combined to comprehensively determine whether the error rate of the current candidate read voltage is at the lowest point, if not, the candidate read voltage is adjusted to enter the next round of iteration; in the solution, since it is required to refer to the original data corresponding to the current candidate read voltage and the plurality of voltages on the two sides of the current candidate read voltage to determine whether the error rate of the current candidate read voltage is at the lowest point, so that the error rate in the wider voltage range on the two sides of the current candidate read voltage can be considered, the noise interference is effectively reduced, the accuracy of the read voltage of the memory device is improved, and the accuracy of subsequent data reading is further ensured.

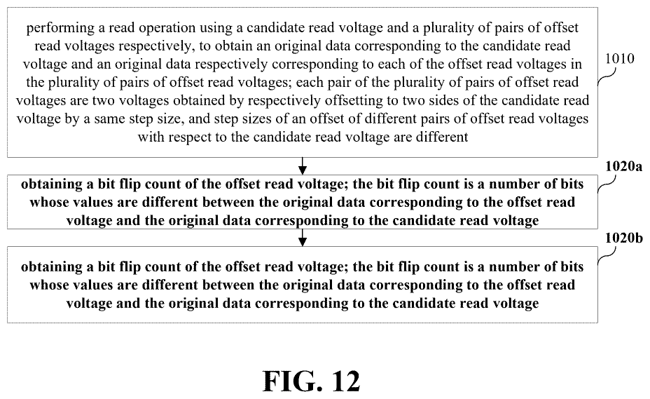

Based on the example shown in FIG. 10, referring to FIG. 12, FIG. 12 is a flowchart of an operating method of a memory system according to another example of the present disclosure. As shown in FIG. 12, the above operation 1020 may be implemented as the following operation 1020a and operation 1020b.

Operation 1020a: obtain a bit flip count of the offset read voltage; the bit flip count is a number of bits whose values are different between the original data corresponding to the offset read voltage and the original data corresponding to the candidate read voltage.

For any one of the plurality of pairs of offset read voltages, the bit flip count corresponding to the offset read voltage represents a number of bits whose values are different between the original data corresponding to the offset read voltage and the original data corresponding to the candidate read voltage, that is, a number of flipped bits in the read original data in the process of changing the read voltage from the offset read voltage to the candidate read voltage, or in the process of changing the read voltage from the candidate read voltage to the offset read voltage.

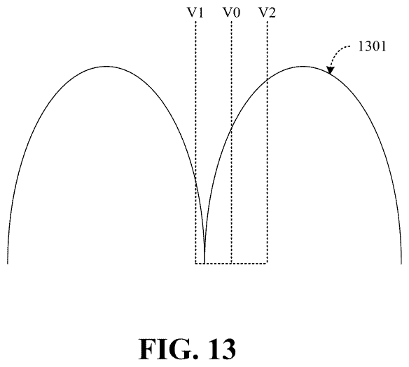

Specifically, referring to FIG. 13, FIG. 13 shows a diagram of a relationship between a voltage and a number of flipped bits according to an example of the present disclosure. FIG. 13 shows the change of the number of flipped bits in the read original data in the read voltage change process with a fluctuation variation curve 1301, wherein the abscissa is the read voltage, and the ordinate is the number of flipped bits in the read original data under the read voltage span per unit. In this case, for any two of the read voltages, an area under a curve corresponding to the two read voltages in the curve 1301 may represent the number of flipped bits in the read original data under the voltage span corresponding to the two read voltages.

Specifically, for example, assuming that in a round of iteration, the candidate read voltage is V0, and the plurality of pairs of offset read voltages are V1, V2, V3 and V4, respectively, where V1 and V2 are located on the left side of V0, V3 and V4 are located on the right side of V0, and taking the offset read voltage V2 as an example, the area under the curve corresponding to offset read voltage V2 and candidate read voltage V0 in curve 1301 is the bit flip count of offset read voltage V2.

The bit flip count of the offset read voltage may be obtained by comparing the original data of the offset read voltage and the original data of the candidate read voltage bit-by-bit by the memory system.

Alternatively, the bit flip count of the offset read voltage may be directly obtained in a process of performing a read operation by the memory system.

Operation 1020b: adjust the candidate read voltage when the respective bit flip counts of the plurality of pairs of offset read voltages do not satisfy a specified condition.

In the examples of the present disclosure, the memory system obtaining the bit flip counts of the respective offset read voltages is equivalent to determining that the number of flipped bits when the read voltage changes between different offset read voltages and candidate read voltages, and the bit flip counts of the different offset read voltages may reflect a change trend of the number of flipped bits in the read voltage span interval in which the plurality of pairs of offset read voltages and the candidate read voltages are located, and therefore, the memory system may determine whether the candidate read voltage needs to be adjusted based on the respective bit flip counts of the plurality of pairs of offset read voltages, and determine how to adjust the candidate read voltage.

According to the solution shown in the example of the present disclosure, the change trend of the number of flipped bits in the read voltage span interval where the plurality of pairs of offset read voltages and the candidate read voltages are located can be determined through the respective bit flip counts of the plurality of pairs of offset read voltages, so that whether the candidate read voltage needs to be adjusted, and how to adjust the candidate read voltage is determined, thereby providing an achievable solution for adjusting the candidate read voltage through the original data corresponding to the candidate read voltage and the original data of the plurality of pairs of offset read voltages.

Based on the solution as shown in any one or more of the foregoing examples, in some examples, the foregoing operation 1020b may be implemented as follows: obtain a composite flip count difference according to the respective bit flip counts of the plurality of pairs of offset read voltages; and adjust the candidate read voltage when an absolute value of the composite flip count difference is not less than a difference threshold.

The difference threshold may be a threshold preset by the developer.

The memory system may substitute the respective bit flip counts of the plurality of offset read voltages into a preset calculation formula to calculate the composite flip count difference.

According to the solution shown in the examples of the present disclosure, the memory system may calculate a composite flip count difference according to the respective bit flip counts of the plurality of offset read voltages, and determine whether to adjust the candidate read voltage by comparing the composite flip count difference and a preset threshold, so that the efficiency of determining whether to adjust the candidate read voltage may be ensured. Specifically, if the composite flip count difference is less than the preset difference threshold, it may be considered that the candidate read voltage is close enough to the optimal read voltage, and in this case, the candidate read voltage may not be adjusted; otherwise, if the composite flip count difference is not less than the preset difference threshold, it may be considered that the candidate read voltage is still relatively far away from the optimal read voltage (the difference between the candidate read voltage and the optimal read voltage is still relatively large), and in this case, the candidate read voltage may be adjusted before entering the next round of iteration process.

Based on the solution shown in any one or more of the foregoing examples, in some examples, the operating method of the memory system further comprises: a read voltage of the memory device is determined as the candidate read voltage when the respective bit flip counts of the plurality of pairs of offset read voltages satisfy the specified condition.

For example, if the composite flip count difference is less than a preset difference threshold, it is determined that the candidate read voltage is close enough to the optimal read voltage, and in this case, the memory system may use the candidate read voltage as an optimal read voltage of the memory device. For example, taking the threshold voltage distribution of the TLC shown in FIG. 7 as an example, seven read voltages are assigned to three memory pages, and for each read voltage corresponding to each memory page, or a part of read voltage in each memory page, the memory system may read the original data and adjust the candidate read voltage according to the solution shown in the foregoing examples, to find the corresponding optimal read voltage. For example, taking the above candidate read voltage corresponding to Vr1 in FIG. 7 as an example, if the composite flip count difference is less than a preset difference threshold, the candidate read voltage is used as a corresponding optimal read voltage (that is, as a new Vr1).

Based on the solution as shown in any one or more of the above examples, in some examples, the process of obtaining the composite flip count difference according to the respective bit flip counts of the plurality of pairs of offset read voltages may be as follows: obtaining flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtaining the composite flip count difference according to the flip count differences respectively corresponding to the plurality of pairs of offset read voltages.

For example, in a possible implementation, the memory system may perform addition operation on the flip count differences respectively corresponding to the plurality of pairs of offset read voltages to obtain the composite flip count difference.

In the process of calculating the composite flip count difference, for two offset read voltages in each pair of offset read voltages, the memory system may first calculate a difference between the bit flip counts of the two offset read voltages (that is, the flip count difference), and then combine the flip count differences corresponding to each pair of offset read voltages to obtain the composite flip count difference. Referring to FIG. 13, for any candidate read voltage V0, two offset read voltages V1 and V2 at a position with the same offset step size are determined on both sides of the candidate read voltage V0, because the number of flipped bits between the offset read voltage and the candidate read voltage may be represented by the area of the two read voltages under the curve 1301 (that is, the bit flip count of the offset read voltage), the closer the candidate read voltage is to the valley of the curve 1301, the smaller the difference between the bit flip counts of the two offset read voltages at the position with the same offset step size on the two sides of the candidate read voltage (that is, the flip count difference). Therefore, the flip count difference of each pair of offset read voltages may indirectly indicate that the distance between the offset read voltage and the optimal read voltage. Therefore, in combination with the composite flip count difference obtained by the flip count differences respectively corresponding to the plurality of pairs of offset read voltages, it may be accurately indicated whether to continue to adjust the candidate read voltage.

Based on the solution shown in any one or more of the above examples, in some examples, the process of obtaining the composite flip count difference according to the flip count difference respectively corresponding to the plurality of pairs of offset read voltages may be as follows: performing a weighted operation on the flip count differences respectively corresponding to the plurality of pairs of offset read voltages to obtain the composite flip count difference.

For example, in a possible implementation, the memory system may perform weighted summation on the flip count differences respectively corresponding to the plurality of pairs of offset read voltages to obtain the composite flip count difference.

Taking FIG. 13 as an example, it is mentioned above that the number of flipped bits between the offset read voltage and the candidate read voltage may be represented by the area of the two read voltages under the curve 1301 (that is, the bit flip count of the offset read voltage), for an offset read voltage, the bit flip count of the offset read voltage is related to the offset value between the offset read voltage and the candidate read voltage, there is obvious difference between the bit flip counts at different offset values, and correspondingly, there is difference between the influences of the noise on the corresponding bit flip count; and the flip count difference of each pair of offset read voltages is the difference between the bit flip counts of the two offset read voltages in the pair of offset read voltages, therefore, the influence of the noise in the memory device on the flip count difference of different pairs of offset read voltages is also different. In order to eliminate the influence of noise as much as possible, when calculating the composite flip count difference, the flip count difference respectively corresponding to the plurality of pairs of offset read voltages may be set to different weights, thereby ensuring the accuracy of subsequently determining whether to adjust the candidate read voltage by the composite flip count difference.

Based on the solution shown in any one or more of the above examples, in some examples, in the above weighting operation, a weight of the flip count difference is positively correlated with an offset value of the offset read voltage with respect to the candidate read voltage.

Still taking FIG. 13 as an example, for an offset read voltage, the larger the offset value of the offset read voltage with respect to the candidate read voltage is, the larger the bit flip count is, and the larger the bit flip count is, the smaller the influence of the noise is; in contrast, the smaller the offset value of the offset read voltage with respect to the candidate read voltage is, the smaller the bit flip count is, and the smaller the bit flip count is, the larger the influence of the noise is; in this regard, in the examples of the present disclosure, when the memory system performs a weighted operation on the flip count difference respectively corresponding to the plurality of pairs of offset read voltages to obtain the composite flip count difference, a smaller weight can be set for an offset read voltage close to the candidate read voltage, and a larger weight is set for an offset read voltage far away from the candidate read voltage, so as to suppress the influence of the noise on the bit flip count of the offset read voltage close to the candidate read voltage as much as possible.

Based on the solution shown in any one or more of the above examples, in some examples, the flip count difference is a difference obtained by subtracting a second type of bit flip count from a first type of bit flip count; the first type of bit flip count is a number of bits whose values are different between the original data corresponding to a first offset voltage in a pair of offset read voltages and the original data corresponding to the candidate read voltage; and the second type of bit flip count is a number of bits whose values are different between the original data corresponding to a second offset voltage in the same pair of offset read voltages and the original data corresponding to the candidate read voltage.

The first offset read voltage refers to an offset read voltage on the right side of the candidate read voltage in a pair of offset read voltages; and the second offset read voltage refers to an offset read voltage on the left side of the candidate read voltage in a pair of offset read voltages.

Alternatively, the first offset read voltage refers to an offset read voltage on the left side of the candidate read voltage in a pair of offset read voltages; and the second offset read voltage refers to an offset read voltage on the right side of the candidate read voltage in a pair of offset read voltages.

In the examples of the present disclosure, for any pair of offset read voltages, the difference between the respective bit flip counts of the pair of offset read voltages may be a positive value or a negative value, and for this reason, when calculating the respective flip count differences of the plurality of pairs of offset read voltages, the memory system needs to calculate a difference between the bit flip counts according to the same calculation direction for the plurality of pairs of offset read voltages; specifically, the flip count difference of the plurality of pairs of offset read voltages is a bit flip count of the offset read voltage on the left side in each pair of offset read voltages subtracting from a bit flip count of the offset read voltage on the right side in each pair of offset read voltages, or is a bit flip count of the offset read voltage on the right side in each pair of offset read voltages subtracting from a bit flip count of the offset read voltage on the left side in each pair of offset read voltages. According to the solution, the uniformity of calculating the flip count difference of the plurality of pairs of offset reading voltages can be ensured, and then the accuracy of subsequently determining whether to adjust the candidate reading voltage through the composite flip count difference can be ensured.

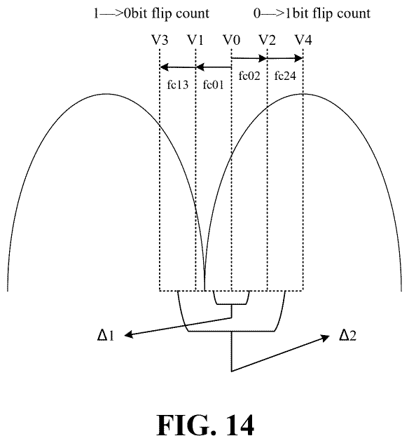

Based on the solutions shown in any one or more of the foregoing examples, in some examples, referring to FIG. 14, FIG. 14 shows a schematic diagram of calculating a composite flip count difference according to an example of the present disclosure. As shown in FIG. 14, in a round of iteration, the candidate read voltage is V0, V1 to V4 are four offset read voltages, wherein V1 and V2 constitute a pair of offset read voltages, and V3 and V4 constitute another pair of offset read voltages; where fc01 is a bit flip count corresponding to the offset read voltage V1 (which may be considered as the bit flip count of a value flipped from 1 to 0 in the original data of the candidate read voltage V0 with respect to the original data of the offset read voltage V1), fc02 is the bit flip count corresponding to the offset read voltage V2 (which may be considered as the bit flip count of a value flipped from 0 to 1 in the original data of the candidate read voltage V0 with respect to the original data of the offset read voltage V2), the fc13 is a bit flip count corresponding to the offset read voltage V3 (which may be considered as the bit flip count of a value flipped from 1 to 0 in the original data of the candidate read voltage V0 with respect to the original data of the offset read voltage V3), and fc24 is a bit flip count corresponding to the offset read voltage V4 (which may be considered as the bit flip count of a value flipped from 0 to 1 in the original data of the candidate read voltage V0 with respect to the original data of the offset read voltage V4); wherein the composite flip count difference Δ may be calculated according to following formulas 1 to 3 shown below:

$$Δ1 = fc 02 - fc 01 \qquad ( 1 )$$

$$Δ2 = fc 24 - fc 13 \qquad ( 2 )$$

$$Δ = 1 * Δ1 + 2 * Δ2 \qquad ( 3 )$$

The example corresponding to FIG. 14 is described by taking only two pairs of offset read voltages as an example, and optionally, there may also be more pairs of offset read voltages.

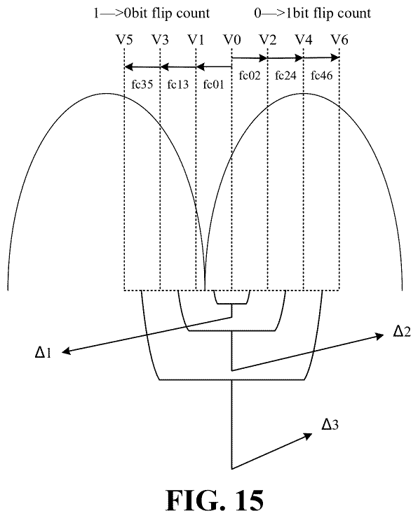

For example, referring to FIG. 15, FIG. 15 shows another schematic diagram of calculating a composite flip count difference according to an example of the present disclosure. As shown in FIG. 15, in a round of iteration, the candidate read voltage is V0, V1 to V6 are six offset read voltages, wherein V1 and V2 constitute a pair of offset read voltages, V3 and V4 constitute a pair of offset read voltages, and V5 and V6 constitute a pair of offset read voltages; wherein fc01 is a bit flip count corresponding to the offset read voltage V1, fc02 is a bit flip count corresponding to the offset read voltage V2, fc13 is a bit flip count corresponding to the offset read voltage V3, fc24 is a bit flip count corresponding to the offset read voltage V4; fc35 is a bit flip count corresponding to the offset read voltage V5, and fc46 is a bit flip count corresponding to the offset read voltage V6; wherein the composite flip count difference Δ may be calculated according to following formulas 4 to 7 shown below:

$$Δ1 = fc 02 - fc 01 \qquad ( 4 )$$

$$Δ2 = fc 24 - fc 13 \qquad ( 5 )$$

$$Δ3 = fc 46 - fc 35 \qquad ( 6 )$$

$$Δ = 1 * Δ1 + 2 * Δ2 + 4 * Δ3 \qquad ( 7 )$$

In another possible implementation, the bit flip count of the offset read voltage may also be a number of bits whose values are different between the original data corresponding to the offset read voltage and the original data corresponding to the comparison read voltage of the offset read voltage. The comparison read voltage of the offset read voltage is a read voltage closest to the offset voltage in a direction towards the candidate read voltage in the candidate read voltage and other offset read voltages of the plurality of pairs of offset read voltages.

Optionally, the first type of bit flip count is a number of bits whose values are different between the original data corresponding to a first offset voltage in a pair of offset read voltages and the original data corresponding to a comparison read voltage of the first offset read voltage; and the second type of bit flip count is a number of bits whose values are different between the original data corresponding to a comparison read voltage of a second offset voltage in the same pair of offset read voltages and the original data corresponding to the candidate read voltage.

For example, taking the FIG. 14 as an example, the fc13 is the number of bits whose values are different between the original data of the candidate read voltage V1 with respect to the original data of the offset read voltage V3 (which may be considered as the bit flip count of a value flipped from 1 to 0 in the original data of the candidate read voltage V1 with respect to the original data of the offset read voltage V3); and fc24 is the number of bits whose values are different between the original data of the candidate read voltage V2 with respect to the original data of the offset read voltage V4 (which may be considered as the bit flip count of a value flipped from 0 to 1 in the original data of the candidate read voltage V2 with respect to the original data of the offset read voltage V3).

Based on the solution shown in any one or more of the foregoing examples, in some examples, the process of obtaining the composite flip count difference according to the respective bit flip counts of the plurality of pairs of offset read voltages comprises: obtaining a first mixed bit flip count according to respective bit flip counts of voltages other than a third offset voltage in the plurality of pairs of offset read voltages; the third offset voltage is a voltage of the plurality of pairs of offset read voltages with a offset having longest step size to a left side of the candidate read voltage; obtaining a second mixed bit flip count according to respective bit flip counts of voltages other than a fourth offset voltage in the plurality of pairs of offset read voltages; the fourth offset voltage is a voltage in the plurality of pairs of offset read voltages with a offset having longest step size to a right side of the candidate read voltage; and determining a difference between the mixed bit flip count and the second mixed bit flip count as the composite flip count difference.

In the examples of the present disclosure, the memory system may also calculate a mixed bit flip calculation by the bit flip counts of offset read voltages other than the leftmost offset read voltage in the offset read voltages; and the memory system further calculates another mixed bit flip calculation by the bit flip counts of offset read voltages other than the rightmost offset read voltage in the offset read voltages; and then use the difference between the two mixed bit flip counts as the composite flip count difference, which may also indicate a distance between the candidate read voltage and the optimal read voltage, thereby providing an achievable solution for estimating a distance between the candidate read voltage and the optimal read voltage by the bit flip count of the offset read voltage.

Based on the solution shown in any one or more of the foregoing examples, in some examples, the process of obtaining the first mixed bit flip count according to the respective bit flip counts of offset voltages other than the third offset voltage in the plurality of pairs of offset read voltages comprises: performing a weighted operation on respective bit flip counts of offset voltages other than the third offset voltage in the plurality of pairs of offset read voltages to obtain the first mixed bit flip count.

Correspondingly, the obtaining the second mixed bit flip count according to the respective bit flip counts of offset voltages other than the fourth offset voltage in the plurality of pairs of offset read voltages comprises: performing a weighted operation on respective bit flip counts of offset voltages other than the fourth offset voltage in the plurality of pairs of offset read voltages to obtain the second mixed bit flip count.

In the examples of the present disclosure, for offset read voltages other than the rightmost or leftmost offset read voltages in the plurality of pairs of offset read voltages, the weights of the offset read voltages may be preset by the developer, for example, the developer may set different weights for different offset read voltages according to the test result, thereby ensuring that the subsequently calculated composite flip count difference can accurately indicate the distance between the candidate read voltage and the optimal read voltage, and ensuring the accuracy of determining whether to adjust the candidate read voltage.

Based on the solution shown in any one or more of the above examples, in some examples, the process of adjusting the candidate read voltage may be as follows: determining an offset direction for adjusting the candidate read voltage and an amount of offset for adjusting the candidate read voltage according to a sign of the composite flip count difference; and offsetting the candidate read voltage according to the current offset direction for adjusting the candidate read voltage and the current amount of offset for adjusting the candidate read voltage to obtain an adjusted candidate read voltage

Based on the solution shown in any one or more of the above examples, in some examples, the process of offsetting the candidate read voltage according to the current offset direction for adjusting the candidate read voltage and the current amount of offset for adjusting the candidate read voltage to obtain an adjusted candidate read voltage comprises: offsetting the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In the examples of the present disclosure, the sign of the composite flip count difference may represent the direction of the optimal read voltage with respect to the candidate read voltage, and therefore, the offset direction and amount of offset for adjusting the candidate read voltage may be determined by the sign of the composite flip count difference.

Based on the solution shown in any one or more of the foregoing examples, in some examples, the determining the current offset direction for adjusting the candidate read voltage and the current amount of offset for adjusting the candidate read voltage according to the sign of the composite flip count difference comprises:

determining the current offset direction for adjusting the candidate read voltage according to the sign of the composite flip count difference; and determining the current amount of offset for adjusting the candidate read voltage according to the current offset direction for adjusting the candidate read voltage and a last offset direction for updating the candidate read voltage.

For example, still referring to FIG. 14, the candidate read voltage V0 is on the right side of the optimal read voltage (corresponding to the read voltage at the valley of the curve in FIG. 13), taking the composite flip count difference being calculated by using the above formulas 1 to 3 as an example, in this case, fc02 is greater than fc01, and fc24 is greater than fc13, then the composite flip count difference Δ is positive; otherwise, if the candidate read voltage V0 is on the left side of the optimal read voltage, then fc02 is less than fc01, and fc24 is less than fc13, in this case, the composite flip count difference Δ is negative; based on the foregoing principle, by the sign of the composite flip count difference Δ, the memory system may determine the offset direction for adjusting the candidate read voltage; specifically, when the composite flip count difference Δ is positive, the memory system may determine that the candidate read voltage V0 is on the right side of the optimal read voltage, and determine that the offset direction for adjusting the candidate read voltage is to the left; in contrast, when the composite flip count difference Δ is negative, the memory system may determine that the candidate read voltage V0 is on the left side of the optimal read voltage, and determine that the offset direction for adjusting the candidate read voltage is to the right.

In addition, base on determining the current offset direction for adjusting the candidate read voltage, the last offset direction for adjusting the candidate read voltage may be compared, so as to determine an amount of offset for the candidate read voltage, for example, if the current offset direction for adjusting the candidate read voltage is the same as the last offset direction for adjusting the candidate read voltage, it indicates that the offset process of the candidate read voltage has not passed through the valley, and in this case, it cannot be determined that the distance between the optimal read voltage and the candidate read voltage, and in this case, a larger offset may be determined to offset the candidate read voltage, in order to approach the optimal read voltage as soon as possible; in contrast, if the current offset direction for adjusting the candidate read voltage is different from the last offset direction for adjusting the candidate read voltage, it indicates that the last offset of the candidate read voltage has passed through the valley, and in this case, a smaller offset may be determined to offset the candidate read voltage, in order to avoid excessive offset, thereby ensuring accuracy of offsetting the candidate read voltage.

In summary, according to the solution shown in the examples of the present disclosure, the memory system may accurately determine the offset direction by the sign of the composite flip count difference, and compare the current offset direction for adjusting the candidate read voltage with the last offset direction for adjusting the candidate read voltage to determine an appropriate offset, thereby ensuring the efficiency of finding the optimal read voltage.

Based on the solution shown in any one or more of the foregoing examples, in some examples, the determining the current amount of offset for adjusting the candidate read voltage according to the current offset direction for adjusting the candidate read voltage and the last offset direction for adjusting the candidate read voltage comprises: the current amount of offset for adjusting the candidate read voltage is determined as the last amount of offset for adjusting the candidate read voltage when the current offset direction for adjusting the candidate read voltage is the same as the last offset direction for adjusting the candidate read voltage; and the current amount of offset for adjusting the candidate read voltage is determined as half of the last amount of offset for adjusting the candidate read voltage when the current offset direction for adjusting the candidate read voltage is different from the last offset direction for adjusting the candidate read voltage.

In the examples of the present disclosure, the memory system can continue to use the last amount of offset for adjusting the candidate read voltage when detecting that the current offset direction for adjusting the candidate read voltage is the same as the last offset direction for adjusting the candidate read voltage; and can use half of the last amount of offset for adjusting the candidate read voltage as the current amount of offset for adjusting the candidate read voltage when detecting that the current offset direction for adjusting the candidate read voltage is different from the last offset direction for adjusting the candidate read voltage, so that the optimal read voltage is gradually approached by gradually reducing the offset, and both the accuracy and efficiency of finding the optimal read voltage are considered.

Based on the solution shown in any one or more of the foregoing examples, in some examples, the operating method of the memory system further comprises: determining that the candidate read voltage is an optimal read voltage of the memory device when the current amount of offset for adjusting the candidate read voltage is not greater than the offset threshold.

In the examples of the present disclosure, if the amount of offset for adjusting the candidate read voltage is less than or equal to a certain offset threshold (for example, the offset threshold may be the base offset/unit offset step size), it indicates that the candidate read voltage have been sufficiently close to the optimal read voltage, and in this case, the candidate read voltage may be used as an optimal read voltage of the memory device, thereby avoiding unlimited adjustment of the candidate read voltage, and considering the efficiency of determining the optimal read voltage while ensuring that the determined optimal read voltage is sufficiently accurate.

The base offset/unit offset step size may be preset in the memory system/memory device. In some examples, each time the memory system adjusts the candidate read voltage, the adjusted offset may be set as an integer times of the base offset/unit offset step size. For example, when the memory system adjusts the candidate read voltage for the first time, the adjusted offset may be set as 8 times of the base offset/unit offset step size, and in the subsequent adjustments, if the adjustment direction is consistent with the last adjustment direction, the amount of offset for adjustment is kept unchanged, and if the adjustment direction is inconsistent with the last adjustment direction, the amount of offset for adjustment is halved, that is, the subsequent adjustment offsets may be set to 4 times, 2 times, 1 times, etc. of the basic offset/unit offset step size, and when the adjustment offset is set to 1 times (that is, the adjustment offset is equal to a certain offset threshold), an optimal read voltage of the memory device is determined as the current candidate read voltage.

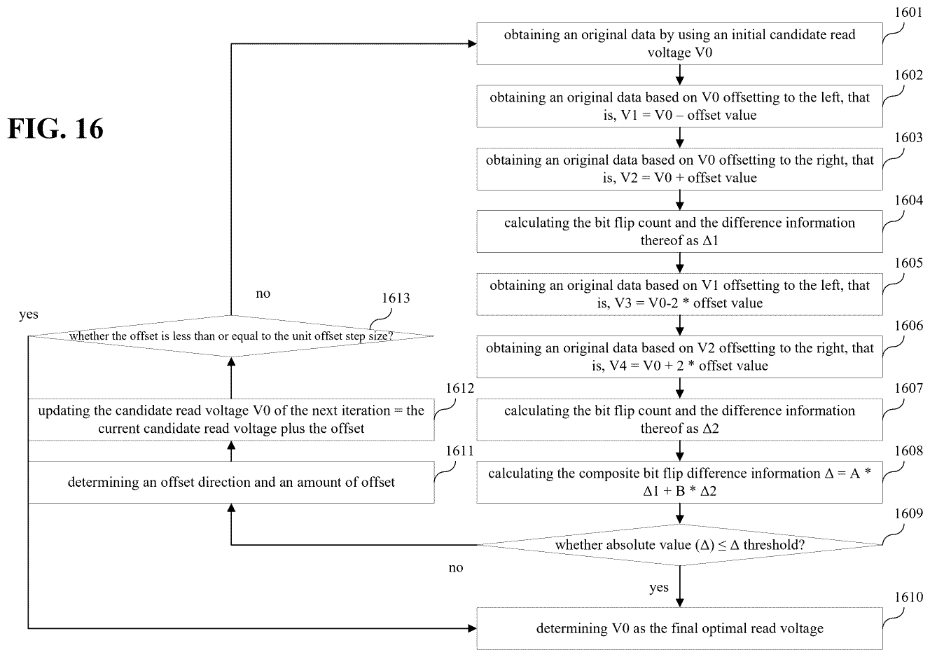

Based on the solutions shown in any one or more of the foregoing examples, referring to FIG. 16, FIG. 16 shows a schematic flowchart of determining an optimal read voltage in an iterative manner according to an example of the present disclosure. With reference to the candidate read voltage and the two pairs of offset read voltages shown in FIG. 14, as shown in FIG. 16, the process in which the memory system determines an optimal read voltage in an iterative manner may be as follows.

Operation 1601: obtaining the original data by using an initial candidate read voltage V0.

For example, the memory system may perform a read operation on one memory page or a group of memory cells in the memory device by using V0, to obtain an original data corresponding to V0 in the memory page or the group of memory cells. The initial V0 may be a preset initial read voltage for each read voltage; for example, taking FIG. 7 as an example, the corresponding initial read voltage is preset for Vr1 to Vr7 respectively in the memory system/memory cell; when the memory system again searches for the optimal read voltage for a certain read voltage (for example, Vr1) in Vr1 to Vr7, the initial read voltage corresponding to Vr1 may be set as the initial candidate read voltage V0. Alternatively, the initial V0 may be the previously used optimal read voltage; for example, assuming that the optimal read voltage of Vr1 needs to be re-determined, Vr1 used before the current time may be used as the initial candidate read voltage V0.

Operation 1602: obtaining the original data based on V0 offsetting to the left, that is, V1=V0−offset value.

The memory system may offset to the left by an offset value based on V0 to obtain an offset read voltage V1, and perform a read operation on one memory page or a group of memory cells in the memory device by using V1 to obtain the original data corresponding to V1 in the memory page or the group of memory cells.

Operation 1603: obtaining the original data based on V0 offsetting to the right, that is, V2=V0+offset value.

The memory system may offset to the right by an offset value based on V0 to obtain an offset read voltage V2, and perform a read operation on one memory page or a group of memory cells in the memory device by using V2 to obtain the original data corresponding to V2 in the memory page or the group of memory cells. A read operation is performed on a same memory page or a group of memory cells in the memory device by using V0, V1 and V2 respectively.

Operation 1604, the bit flip count and the difference information thereof are calculated as Δ1.

The memory system may calculate the bit flip count difference Δ1 corresponding to the pair of offset read voltages V1 and V2 by using the above formula 1.

Operation 1605: obtaining the original data based on V1 offsetting to the left, that is, V3=V0−2*offset value.

The memory system may offset to the left by an offset value based on V1 to obtain an offset read voltage V3, and perform a read operation on one memory page or a group of memory cells in the memory device by using V3 to obtain the original data corresponding to V3 in the memory page or the group of memory cells.

Operation 1606: obtaining original data based on V2 offsetting to the right, that is, V4=V0+2*offset value.

The memory system may offset to the right by an offset value based on V2 to obtain an offset read voltage V4, and perform a read operation on one memory page or a group of memory cells in the memory device by using V4 to obtain the original data corresponding to V4 in the memory page or the group of memory cells. A read operation is performed on a same memory page or a group of memory cells in the memory device by using V0, V1, V2, V3 and V4 respectively.

Operation 1607, the bit flip count and the difference information thereof are calculated as Δ2.

The memory system may calculate the bit flip count difference Δ2 corresponding to the pair of offset read voltages V4 and V5 by using the above formula 2.

Operation 1608: calculating the composite bit flip difference information Δ=A*Δ1+B*Δ2.

For example, the memory system may calculate the composite bit flip difference information Δ (that is, the composite flip count difference) by using the above formula 3.

Operation 1609: determining whether the absolute value (Δ)≤Δ threshold is satisfied; if yes, proceeding to operation 1610; otherwise, proceeding to operation 1611.

Operation 1610: determining V0 as the final optimal read voltage.

The memory system may take the absolute value of Δ, compare it with a preset Δ threshold (e.g., the difference threshold), and if the absolute value of Δ is less than the Δ threshold, it indicates that V0 has sufficiently been close to the optimal read voltage, and in this case, the optimal read voltage of the memory device may be determined as V0.

Operation 1611: determining an offset direction and an amount of offset.

If the absolute value of Δ is not less than the Δ threshold, it indicates that V0 is not close enough to the optimal read voltage, and in this case, the offset direction and the offset (that is, the amount of offset for adjusting the candidate read voltage) may be determined according to Δ.

Operation 1612: updating the candidate read voltage V0 of the next iteration=the current candidate read voltage plus the amount of offset.

Operation 1613: determining whether the offset is less than or equal to the unit offset step size, if yes, proceeding to operation 1610; otherwise, returning to operation 1601.

After determining the amount of offset for adjusting the candidate read voltage, if the amount of offset is less than or equal to 1 unit offset step size, an optimal read voltage of the memory device is determined as V0.

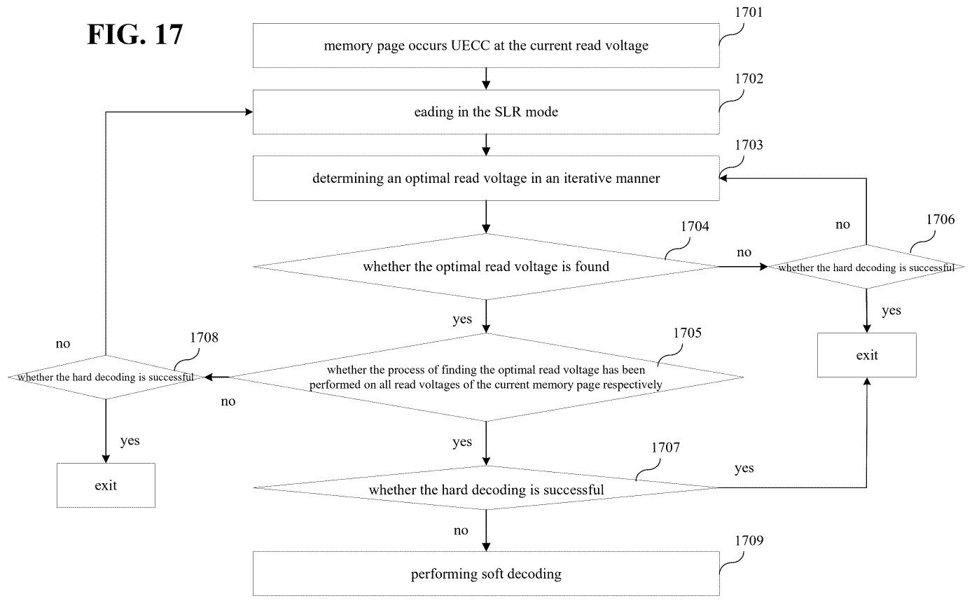

The method for determining the optimal read voltage of the memory device in an iterative manner shown in the foregoing example of the present disclosure may be applied in a single-level read mode. For example, referring to FIG. 17, FIG. 17 shows a schematic flowchart of data reading according to an example of the present disclosure. Taking the following as an example: the optimal read voltage is determined in the unit of memory page, as shown in FIG. 17, the data reading process may be as follows.

Operation 1701: The memory page occurs an uncorrectable error correction code (UECC) at the current read voltage.

When the memory system uses a group of read voltages to read a data on a certain memory page, if the UECC occurs, the read fails, and in this case, the optimal read voltage of the memory page needs to be re-determined. For example, taking the LP of the TLC shown in FIG. 7 as an example, the group of read voltages of the LP comprise Vr1 and Vr5; if the memory system uses the existing Vr1 and Vr5 to read the data in the memory device, it is determined that the data in the LP occurs UECC, and in this case, the memory system may re-determine the optimal read voltage for at least one of Vr1 and Vr5.

Operation 1702: reading in the SLR mode.

The memory system may subsequently read the memory page in the SLR mode in order to determine a new optimal read voltage of the memory page.

For example, still taking the LP of the TLC shown in FIG. 7 as an example, the memory system may read the LP in the SLR mode by using the candidate read voltage and the offset read voltage corresponding to the Vr1 respectively, to obtain the original data for determining the optimal read voltage of the Vr1.

Operation 1703: determining an optimal read voltage in an iterative manner.

The memory system may determine the corresponding optimal read voltage by using the solutions shown in the foregoing examples of the present disclosure. For example, the memory system may determine the corresponding optimal read voltage by using the process shown in FIG. 16.

For example, still taking the LP of the TLC shown in FIG. 7 as an example, after reading the LP in the SLR mode by using the candidate read voltage and the offset read voltage corresponding to Vr1 respectively, the memory system may search for the optimal read voltage of Vr1 according to the read original data.

Operation 1704: determining whether the optimal read voltage is found; if so, proceeding to operation 1705; otherwise, proceeding to operation 1706.

For example, still taking the LP of the TLC shown in FIG. 7 as an example, the memory system may determine whether the optimal read voltage of Vr1 is found by using the flow shown in FIG. 16.

Operation 1705: determining whether the process of finding the optimal read voltage has been performed on all read voltages of the current memory page respectively; if so, proceeding to operation 1707; otherwise, proceeding to operation 1708.

For example, still taking the LP of the TLC shown in FIG. 7 as an example, the memory system determines that the process of finding the optimal read voltage has not been performed on all read voltages of the LP respectively after searching for the optimal read voltage of Vr1, and in this case, proceeding to operation 1708; correspondingly, if the memory system finds the optimal read voltage of Vr5 according to operation 1702 to operation 1704 after finding the optimal read voltage of Vr1, then after finding the optimal read voltage of Vr5, it may be determined that the process of finding the optimal read voltage has been performed on all read voltages of the LP, and in this case, proceeding to operation 1707.

Operation 1706: determining whether a result of reading the current memory page by using the set of optimal read voltages that are not completely determined is successfully hard decoded, if so, exit the process, otherwise, proceeding to operation 1703.

When searching for an optimal read voltage of the current memory page, if the memory system fails to find the optimal read voltage, the current memory page may be read (read by the non-SLR mode) by using an existing set of optimal read voltages that are not completely determined in the current memory page (that is, read voltages that have been found or updated and read voltages that have not been found or updated in all read voltages of the current memory page), and hard decoding is performed on the read result, and if the hard decoding is successful, the process of determining each optimal read voltage of the memory page may be ended, and in this case, the plurality of read voltages corresponding to the passed hard decoding may be used as a set of optimal read voltages of the current memory page; and if the hard decoding fails, returning to operation 1703 to continue to search for the next optimal read voltage.

Operation 1707: determining whether a result of reading the current memory page by using the determined set of optimal read voltages is successfully hard decoded, if so, exit the process, otherwise, proceeding to operation 1709.

When all the optimal read voltages of the current memory page are determined, all the determined optimal read voltages are used to read the current memory page, and hard decoding is performed on the read result, if the hard decoding is successful, the process of determining the optimal read voltage of the current memory page ends, and if not, proceeding to operation 1709.

Operation 1708: determining whether a result of reading the current memory page by using the set of optimal read voltages that are not completely determined is successfully hard decoded, if so, exit the process, otherwise, proceeding to operation 1702.

If not all the optimal read voltages of the current memory page are found or updated, the memory system reads the current memory page by using the optimal read voltage that has been found or updated and the read voltage that has not been found or updated in all the read voltages of the current memory page, performs hard decoding on the read result, and if the hard decoding is successful, the determining process of each optimal read voltage of the current memory page ends, and uses the plurality of read voltages corresponding to the passed hard decoding as a set of optimal read voltages of the current memory page; and if the hard decoding fails, return to find the optimal read voltages respectively corresponding to the read voltages of the current memory page.

Operation 1709: performing soft decoding.

When all the optimal read voltages of the current memory page have been found or updated, but the hard decoding fails, the memory system performs soft decoding and continues to perform error correction.

For example, taking the MP of the TLC shown in FIG. 7 as an example, a set of read voltages of the MP comprises Vr2, Vr4, and Vr6; the memory system first finds the optimal read voltage of Vr2, and assuming that the corresponding optimal read voltage is found, then Vr2 is updated to the found optimal read voltage, and in this case, a set of optimal read voltages corresponding to the MP are updated Vr2, un-updated Vr4, and un-updated Vr6 (corresponding to the set of optimal read voltages that are not completely determined in operation 1708); the memory system determines that the optimal read voltage of all read voltages of the MP is not found, reads the MP according to the updated Vr2, the un-updated Vr4, and the un-updated Vr6, and performs hard decoding on the read result; if the hard decoding is successful, the process of finding the optimal read voltage for the MP ends; if the decoding fails, continues to find the optimal read voltage of Vr4; assuming that the memory system does not find the optimal read voltage corresponding to Vr4, the Vr4 remains unchanged, and in this case, the set of optimal read voltages corresponding to the MP is still updated Vr2, the un-updated Vr4 and the un-updated Vr6 (corresponding to the set of optimal read voltages that are not completely determined in operation 1706); the memory system reads the MP according to the updated Vr2, the un-updated Vr4, and the un-updated Vr6, and performs hard decoding on the read result; if the hard decoding is successful, the process of finding the optimal read voltage for the MP ends; if the decoding fails, continues to find the optimal read voltage of Vr6; assuming that the memory system does not find the optimal read voltage corresponding to Vr6, the Vr6 is updated with the found optimal read voltage, and in this case, the set of optimal read voltages corresponding to the MP is the updated Vr2, the un-updated Vr4, and the updated Vr6 (corresponding to the determined set of optimal read voltages in operation 1707); the memory system determines that the optimal read voltage of all read voltages of the MP has been found; and in this case, the memory system reads the MP according to the updated Vr2, the un-updated Vr4, and the updated Vr6, performs hard decoding on the read result, and if the hard decoding is successful, the process of finding the optimal read voltage for the MP ends, and if the decoding fails, performs soft decoding.

In an example of the present disclosure, a memory system is further provided, comprising: one or more memory devices, and a controller coupled to the memory device and configured to control the memory device.

The memory system may be all or part of a mobile phone, a desktop computer, a laptop computer, a tablet computer, a vehicle computer, a game console, a printer, a pointing device, a wearable electronic device, a smart sensor, a virtual reality (VR) device, an augmented reality (AR) device, or any other suitable electronic device having a storage therein.

Optionally, the memory system may comprise a host and a memory subsystem having one or more memory devices and a controller. The host may be a processor (for example, a central processing unit (CPU)) or a system on chip (SoC) (for example, an application processor (AP)) of the electronic device. The host may be configured to send data to the memory device. Alternatively, the host may be configured to receive data from the memory device.

According to some implementations, the controller is further coupled to the host. The controller may manage data stored in the memory device and communicate with the host.

In some implementations, the controller is designed to operate in a low duty cycle environment, such as a secure digital (SD) card, a compact flash memory (CF) card, a universal serial bus (USB) flash drive, or other medium for use in electronic devices such as personal computers, digital cameras, mobile phones, and the like.

In some implementations, the controller is designed for operation in a high duty cycle environment solid state drive (SSD) or embedded Multi Media Card (eMMC), which acts as a data storage for mobile devices such as smartphones, tablets, laptops, and the like, as well as enterprise storage arrays.

The controller may be configured to control operations of the memory device, such as read, erase, and program operations. The controller may also be configured to manage various functions regarding data stored in or to be stored in the memory device, comprising, but not limited to, bad block management, garbage collection, logical-to-physical address translation, wear leveling, and the like. In some implementations, the controller is further configured to process an error correction code (ECC) regarding data read from or written to the memory device.

The controller may also perform any other suitable functions, such as formatting the memory device. The controller may communicate with the external device according to a particular communication protocol.

The controller and one or more memory devices may be integrated into various types of storage devices, e.g., comprised in the same package (e.g., Universal Flash Storage (UFS) package or eMMC package). That is, the memory system may be implemented and packaged into different types of terminal electronics.

Illustratively, a controller and a single memory device may be integrated into a memory card. The memory cards may comprise PC cards (PCMCIA, Personal Computer Memory Card International Association), CF cards, smart media (SM) cards, memory sticks, multimedia cards (MMC, RS-MMC, MMCmicro), SD cards (SD, miniSD, microSD, SDHC), UFS, and the like. The memory card may also comprise a memory card connector coupling the memory card with the host.

Illustratively, the controller and the plurality of memory devices may be integrated into a solid state drive (SSD). In some implementations, the storage capacity and/or operating speed of the solid state drive is greater than the storage capacity and/or the operating speed of the memory card.

The memory device may be implemented as the memory device 100 in any one of the examples shown in FIG. 1 to FIG. 3; the controller may be implemented as the controller 200 in any one of the examples shown in FIG. 1 to FIG. 3.

In the examples of the present disclosure, the controller is configured to: perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes offset of different pairs of offset read voltages with respect to the candidate read voltage are different; and adjust the candidate read voltage based on the original data corresponding to the candidate read voltage and the original data respectively corresponding to each of the offset read voltages in the plurality of pairs of offset read voltages.

In an optional example, the controller is configured to: obtain a bit flip count of the offset read voltage; the bit flip count is a number of bits whose values are different between the original data corresponding to the offset read voltage and the original data corresponding to the candidate read voltage; and adjust the candidate read voltage when the respective bit flip counts of the plurality of pairs of offset read voltages do not satisfy a specified condition.

In an optional example, the controller is configured to: obtain a composite flip count difference according to the respective bit flip counts of the plurality of pairs of offset read voltages; and adjust the candidate read voltage when an absolute value of the composite flip count difference is not less than a difference threshold.

In an optional example, the controller is configured to: obtain flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtain the composite flip count difference according to the flip count differences respectively corresponding to the plurality of pairs of offset read voltages.

In an optional example, the controller is configured to: perform a weighted operation on the flip count differences respectively corresponding to the plurality of pairs of offset read voltages to obtain the composite flip count difference.

In an optional example, in the weighted operation, a weight of the flip count difference is positively correlated with an offset value of the offset read voltage with respect to the candidate read voltage.

In an optional example, the flip count difference is a difference obtained by subtracting a second type of bit flip count from a first type of bit flip count; the first type of bit flip count is a number of bits whose values are different between an original data corresponding to a first offset voltage in a pair of offset read voltages and an original data corresponding to the candidate read voltage; and the second type of bit flip count is a number of bits whose values are different between an original data corresponding to a second offset voltage in the same pair of offset read voltages and an original data corresponding to the candidate read voltage.

In an optional example, the controller is configured to: obtain a first mixed bit flip count according to respective bit flip counts of read voltages other than a third offset voltage in the plurality of pairs of offset read voltages; the third offset voltage is a voltage of the plurality of pairs of offset read voltages with a longest step size for an offset to a left side of the candidate read voltage; obtain a second mixed bit flip count according to respective bit flip counts of read voltages other than a fourth offset voltage in the plurality of pairs of offset read voltages; the fourth offset voltage is a voltage in the plurality of pairs of offset read voltages with a longest step size for an offset to a right side of the candidate read voltage; and obtain a difference between the mixed bit flip count and the second mixed bit flip count as the composite flip count difference.

In an optional example, the controller is configured to: perform a weighted operation on respective bit flip counts of offset voltages other than the third offset voltage in the plurality of pairs of offset read voltages to obtain the first mixed bit flip count; and perform a weighted operation on respective bit flip counts of offset voltages other than the fourth offset voltage in the plurality of pairs of offset read voltages to obtain the second mixed bit flip count.

In an optional example, the controller is further configured to: determine a current offset direction for adjusting the candidate read voltage and a current amount of offset for adjusting the candidate read voltage according to a sign of the composite flip count difference; and offset the candidate read voltage according to the current offset direction for adjusting the candidate read voltage and the current amount of offset for adjusting the candidate read voltage to obtain an adjusted candidate read voltage.

In an optional example, the controller is configured to: determine the current offset direction for adjusting the candidate read voltage according to the sign of the composite flip count difference; and determine the current amount of offset for adjusting the candidate read voltage according to the current offset direction for adjusting the candidate read voltage and a last offset direction for adjusting the candidate read voltage.

In an optional example, the controller is configured to: determine the last amount of offset for adjusting the candidate read voltage as the current amount of offset for adjusting the candidate read voltage when the current offset direction for adjusting the candidate read voltage is the same as the last offset direction for adjusting the candidate read voltage; and determine half of the last amount of offset for adjusting the candidate read voltage as the current amount of offset for adjusting the candidate read voltage when the current offset direction for adjusting the candidate read voltage is different from the last offset direction for adjusting the candidate read voltage.

In an optional example, the controller is configured to: offset the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In an optional example, the controller is further configured to: a read voltage of the memory device is determined as the candidate read voltage when the current amount of offset for adjusting the candidate read voltage is not greater than the offset threshold.

In an optional example, the controller is further configured to: a read voltage of the memory device is determined as the candidate read voltage when the respective bit flip counts of the plurality of pairs of offset read voltages satisfy the specified condition.

In an optional example, the original data is obtained by reading the memory device in a single-level read SLR mode.

In an example of the present disclosure, a memory device is further provided, comprising: a memory cell array; and a peripheral circuit; the peripheral circuit is configured to: perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and adjust the candidate read voltage based on the original data corresponding to the candidate read voltage and the original data respectively corresponding to each of the offset read voltages in the plurality of pairs of offset read voltages.

In an optional example, the peripheral circuit is configured to: obtain a bit flip count of the offset read voltage; the bit flip count is a number of bits whose values are different between the original data corresponding to the offset read voltage and the original data corresponding to the candidate read voltage; and adjust the candidate read voltage when the respective bit flip counts of the plurality of pairs of offset read voltages do not satisfy a specified condition.

In an optional example, the peripheral circuit is configured to: obtain a composite flip count difference according to the respective bit flip counts of the plurality of pairs of offset read voltages; and adjust the candidate read voltage when an absolute value of the composite flip count difference is not less than a difference threshold.

In an optional example, the peripheral circuit is configured to: obtain flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtain the composite flip count difference according to the flip count differences respectively corresponding to the plurality of pairs of offset read voltages.

In an optional example, the peripheral circuit is configured to: perform a weighted operation on the flip count differences respectively corresponding to the plurality of pairs of offset read voltages to obtain the composite flip count difference.

In an optional example, in the weighted operation, a weight of the flip count difference is positively correlated with an offset value of the offset read voltage with respect to the candidate read voltage.

In an optional example, the flip count difference is a difference obtained by subtracting a second type of bit flip count from a first type of bit flip count; the first type of bit flip count is a number of bits whose values are different between the original data corresponding to a first offset voltage in a pair of offset read voltages and the original data corresponding to the candidate read voltage; and the second type of bit flip count is a number of bits whose values are different between the original data corresponding to a second offset voltage in the same pair of offset read voltages and the original data corresponding to the candidate read voltage.

In an optional example, the peripheral circuit is configured to: obtain a first mixed bit flip count according to respective bit flip counts of read voltages other than a third offset voltage in the plurality of pairs of offset read voltages; the third offset voltage is a voltage of the plurality of pairs of offset read voltages with a longest step size for an offset to a left side of the candidate read voltage; obtain a second mixed bit flip count according to respective bit flip counts of read voltages other than a fourth offset voltage in the plurality of pairs of offset read voltages; the fourth offset voltage is a voltage in the plurality of pairs of offset read voltages with a longest step size for an offset to a right side of the candidate read voltage; and obtain a difference between the mixed bit flip count and the second mixed bit flip count as the composite flip count difference.

In an optional example, the peripheral circuit is configured to: perform a weighted operation on respective bit flip counts of offset voltages other than the third offset voltage in the plurality of pairs of offset read voltages to obtain the first mixed bit flip count; and perform a weighted operation on respective bit flip counts of offset voltages other than the fourth offset voltage in the plurality of pairs of offset read voltages to obtain the second mixed bit flip count.

In an optional example, the peripheral circuit is further configured to: determine a current offset direction for adjusting the candidate read voltage and a current amount of offset for adjusting the candidate read voltage according to a sign of the composite flip count difference; and offset the candidate read voltage according to the current offset direction for adjusting the candidate read voltage and the current amount of offset for adjusting the candidate read voltage to obtain an adjusted candidate read voltage.

In an optional example, the peripheral circuit is configured to: determine the current offset direction for adjusting the candidate read voltage according to the sign of the composite flip count difference; and determine the current amount of offset for adjusting the candidate read voltage according to the current offset direction for adjusting the candidate read voltage and a last offset direction for adjusting the candidate read voltage.

In an optional example, the peripheral circuit is configured to: the current amount of offset for adjusting the candidate read voltage is determined as the last amount of offset for adjusting the candidate read voltage when the current offset direction for adjusting the candidate read voltage is the same as the last offset direction for adjusting the candidate read voltage; and the current amount of offset for adjusting the candidate read voltage is determined as half of the last amount of offset for adjusting the candidate read voltage when the current offset direction for adjusting the candidate read voltage is different from the last offset direction for adjusting the candidate read voltage.

In an optional example, the peripheral circuit is configured to: offset the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In an optional example, the peripheral circuit is further configured to: a read voltage of the memory device is determined as the candidate read voltage when the current amount of offset for adjusting the candidate read voltage is not greater than the offset threshold.

In an optional example, the peripheral circuit is further configured to: a read voltage of the memory device is determined as the candidate read voltage when the respective bit flip counts of the plurality of pairs of offset read voltages satisfy the specified condition.

In an optional example, the original data is obtained by reading the memory device in a single-level read SLR mode.

The examples of the present disclosure provides a computer-readable storage medium, the computer-readable storage medium stores an instruction, and the instruction, when executed on a control logic circuit (for example, the micro control unit and the flash control unit) of the controller, implements the operating method of the memory system provided in the foregoing examples.

In the present disclosure, the terms “first” and “second” are for descriptive purposes only and are not to be construed as indicating or implying relative importance. The term “at least one” refers to one or more, and the term “plurality” refers to two or more unless specifically defined otherwise.

The term “and/or” in the present disclosure is merely an association relationship for describing an associated object, it indicates that there may be three relationships, for example, A and/or B may indicate that only A is present, both A and B are present, and only B is present. In addition, the character “/” herein generally indicates that the relationship between the associated objects before and after “/” is “or”.

The present disclosure provides an operating method of a memory system, a memory system, a memory device and a storage medium, in which the accuracy of the read voltage of the memory device can be improved, and then the accuracy of subsequent data reading is ensured. The technical solution is as follows:

According to one aspect, an operating method of a memory system is provided, comprising: performing a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and adjusting the candidate read voltage based on the original data corresponding to the candidate read voltage and the original data respectively corresponding to each of the offset read voltages in the plurality of pairs of offset read voltages.

In an optional example, the adjusting the candidate read voltage based on the original data corresponding to the candidate read voltage and the original data respectively corresponding to each of the offset read voltages in the plurality of pairs of offset read voltages comprises: obtaining a bit flip count of the offset read voltage; the bit flip count is a number of bits whose values are different between the original data corresponding to the offset read voltage and the original data corresponding to the candidate read voltage; and adjusting the candidate read voltage when the respective bit flip counts of the plurality of pairs of offset read voltages do not satisfy a specified condition.

In an optional example, the adjusting the candidate read voltage when the respective bit flip counts of the plurality of pairs of offset read voltages do not satisfy the specified condition comprises: obtaining a composite flip count difference according to the respective bit flip counts of the plurality of pairs of offset read voltages; and adjusting the candidate read voltage when an absolute value of the composite flip count difference is not less than a difference threshold.

In an optional example, the obtaining the composite flip count difference according to the respective bit flip counts of the plurality of pairs of offset read voltages comprises: obtaining flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtaining the composite flip count difference according to the flip count differences respectively corresponding to the plurality of pairs of offset read voltages.

In an optional example, the obtaining the composite flip count difference according to the flip count differences respectively corresponding to the plurality of pairs of offset read voltages comprises: performing a weighted operation on the flip count differences respectively corresponding to the plurality of pairs of offset read voltages to obtain the composite flip count difference.

In an optional example, in the weighted operation, a weight of the flip count difference is positively correlated with an offset value of the offset read voltage with respect to the candidate read voltage.

In an optional example, the flip count difference is a difference obtained by subtracting a second type of bit flip count from a first type of bit flip count; the first type of bit flip count is a number of bits whose values are different between an original data corresponding to a first offset voltage in a pair of offset read voltages and an original data corresponding to the candidate read voltage; and the second type of bit flip count is a number of bits whose values are different between an original data corresponding to a second offset voltage in the same pair of offset read voltages and an original data corresponding to the candidate read voltage.

In an optional example, the obtaining the composite flip count difference according to the respective bit flip counts of the plurality of pairs of offset read voltages comprises: obtaining a first mixed bit flip count according to respective bit flip counts of voltages other than a third offset voltage in the plurality of pairs of offset read voltages; the third offset voltage is a voltage of the plurality of pairs of offset read voltages with a longest step size for an offset to a left side of the candidate read voltage; obtaining a second mixed bit flip count according to respective bit flip counts of voltages other than a fourth offset voltage in the plurality of pairs of offset read voltages; the fourth offset voltage is a voltage in the plurality of pairs of offset read voltages with a longest step size for an offset to a right side of the candidate read voltage; and determining a difference between the mixed bit flip count and the second mixed bit flip count as the composite flip count difference.

In an optional example, the obtaining the first mixed bit flip count according to the respective bit flip counts of offset voltages other than the third offset voltage in the plurality of pairs of offset read voltages comprises: performing a weighted operation on respective bit flip counts of offset voltages other than the third offset voltage in the plurality of pairs of offset read voltages to obtain the first mixed bit flip count; and the obtaining the second mixed bit flip count according to the respective bit flip counts of offset voltages other than the fourth offset voltage in the plurality of pairs of offset read voltages comprises: performing a weighted operation on respective bit flip counts of offset voltages other than the fourth offset voltage in the plurality of pairs of offset read voltages to obtain the second mixed bit flip count.

In an optional example, the adjusting the candidate read voltage comprises: determining an offset direction for adjusting the candidate read voltage and an amount of offset for adjusting the candidate read voltage according to a sign of the composite flip count difference; and offsetting the candidate read voltage according to the current offset direction for adjusting the candidate read voltage and the current amount of offset for adjusting the candidate read voltage to obtain an adjusted candidate read voltage.

In an optional example, the determining the current offset direction for adjusting the candidate read voltage and the current amount of offset for adjusting the candidate read voltage according to the sign of the composite flip count difference comprises: determining the current offset direction for adjusting the candidate read voltage according to the sign of the composite flip count difference; and determining the current amount of offset for adjusting the candidate read voltage according to the current offset direction for adjusting the candidate read voltage and a last offset direction for updating the candidate read voltage.

In an optional example, the determining the current amount of offset for adjusting the candidate read voltage according to the current offset direction for adjusting the candidate read voltage and the last offset direction for adjusting the candidate read voltage comprises: the current amount of offset for adjusting the candidate read voltage is determined as the last amount of offset for adjusting the candidate read voltage when the current offset direction for adjusting the candidate read voltage is the same as the last offset direction for adjusting the candidate read voltage; and the current amount of offset for adjusting the candidate read voltage is determined as half of the last amount of offset for adjusting the candidate read voltage when the current offset direction for adjusting the candidate read voltage is different from the last offset direction for adjusting the candidate read voltage.

In an optional example, the offsetting the candidate read voltage according to the current offset direction for adjusting the candidate read voltage and the current amount of offset for adjusting the candidate read voltage to obtain an adjusted candidate read voltage comprises: offsetting the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In an optional example, the method further comprises: a read voltage of the memory device is determined as the candidate read voltage when the current amount of offset for adjusting the candidate read voltage is not greater than the offset threshold.

In an optional example, the method further comprises: a read voltage of the memory device is determined as the candidate read voltage when the respective bit flip counts of the plurality of pairs of offset read voltages satisfy the specified condition.

In an optional example, the original data is obtained by reading the memory device in a single-level read SLR mode.

According to another aspect, a memory system is provided, comprising: a memory device and a controller; the controller is configured to: perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and adjust the candidate read voltage based on the original data corresponding to the candidate read voltage and the original data respectively corresponding to each of the offset read voltages in the plurality of pairs of offset read voltages.

In an optional example, the controller is configured to: obtain a bit flip count of the offset read voltage; the bit flip count is a number of bits whose values are different between the original data corresponding to the offset read voltage and the original data corresponding to the candidate read voltage; and adjust the candidate read voltage when the respective bit flip counts of the plurality of pairs of offset read voltages do not satisfy a specified condition.

In an optional example, the controller is configured to: obtain a composite flip count difference according to the respective bit flip counts of the plurality of pairs of offset read voltages; and adjust the candidate read voltage when an absolute value of the composite flip count difference is not less than a difference threshold.

In an optional example, the controller is configured to: obtain flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtain the composite flip count difference according to the flip count differences respectively corresponding to the plurality of pairs of offset read voltages.

In an optional example, the controller is configured to: perform a weighted operation on the flip count differences respectively corresponding to the plurality of pairs of offset read voltages to obtain the composite flip count difference.

In an optional example, in the weighted operation, a weight of the flip count difference is positively correlated with an offset value of the offset read voltage with respect to the candidate read voltage.

In an optional example, the flip count difference is a difference obtained by subtracting a second type of bit flip count from a first type of bit flip count; the first type of bit flip count is a number of bits whose values are different between the original data corresponding to a first offset voltage in a pair of offset read voltages and the original data corresponding to the candidate read voltage; and the second type of bit flip count is a number of bits whose values are different between the original data corresponding to a second offset voltage in the same pair of offset read voltages and the original data corresponding to the candidate read voltage.

In an optional example, the controller is configured to: obtain a first mixed bit flip count according to respective bit flip counts of read voltages other than a third offset voltage in the plurality of pairs of offset read voltages; the third offset voltage is a voltage of the plurality of pairs of offset read voltages with a longest step size for an offset to a left side of the candidate read voltage; obtain a second mixed bit flip count according to respective bit flip counts of read voltages other than a fourth offset voltage in the plurality of pairs of offset read voltages; the fourth offset voltage is a voltage in the plurality of pairs of offset read voltages with a longest step size for an offset to a right side of the candidate read voltage; and obtain a difference between the mixed bit flip count and the second mixed bit flip count as the composite flip count difference.

In an optional example, the controller is configured to: perform a weighted operation on respective bit flip counts of offset voltages other than the third offset voltage in the plurality of pairs of offset read voltages to obtain the first mixed bit flip count; and perform a weighted operation on respective bit flip counts of offset voltages other than the fourth offset voltage in the plurality of pairs of offset read voltages to obtain the second mixed bit flip count.

In an optional example, the controller is further configured to: determine a current offset direction for adjusting the candidate read voltage and a current amount of offset for adjusting the candidate read voltage according to a sign of the composite flip count difference; and offset the candidate read voltage according to the current offset direction for adjusting the candidate read voltage and the current amount of offset for adjusting the candidate read voltage to obtain an adjusted candidate read voltage.

In an optional example, the controller is configured to: determine the current offset direction for adjusting the candidate read voltage according to the sign of the composite flip count difference; and determine the current amount of offset for adjusting the candidate read voltage according to the current offset direction for adjusting the candidate read voltage and a last offset direction for adjusting the candidate read voltage.

In an optional example, the controller is configured to: the current amount of offset for adjusting the candidate read voltage is determined as the last amount of offset for adjusting the candidate read voltage when the current offset direction for adjusting the candidate read voltage is the same as the last offset direction for adjusting the candidate read voltage; and the current amount of offset for adjusting the candidate read voltage is determined as half of the last amount of offset for adjusting the candidate read voltage when the current offset direction for adjusting the candidate read voltage is different from the last offset direction for adjusting the candidate read voltage.

In an optional example, the controller is configured to: offset the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In an optional example, the controller is further configured to: a read voltage of the memory device is determined as the candidate read voltage when the current amount of offset for adjusting the candidate read voltage is not greater than the offset threshold.

In an optional example, the controller is further configured to: a read voltage of the memory device is determined as the candidate read voltage when the respective bit flip counts of the plurality of pairs of offset read voltages satisfy the specified condition.

In an optional example, the original data is obtained by reading the memory device in a single-level read SLR mode.

According to another aspect, a memory device is provided, comprising: a memory cell array; and a peripheral circuit; the peripheral circuit is configured to: perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and adjust the candidate read voltage based on the original data corresponding to the candidate read voltage and the original data respectively corresponding to each of the offset read voltages in the plurality of pairs of offset read voltages.

In an optional example, the peripheral circuit is configured to: obtain a bit flip count of the offset read voltage; the bit flip count is a number of bits whose values are different between the original data corresponding to the offset read voltage and the original data corresponding to the candidate read voltage; and adjust the candidate read voltage when the respective bit flip counts of the plurality of pairs of offset read voltages do not satisfy a specified condition.

In an optional example, the peripheral circuit is configured to: obtain a composite flip count difference according to the respective bit flip counts of the plurality of pairs of offset read voltages; and adjust the candidate read voltage when an absolute value of the composite flip count difference is not less than a difference threshold.

In an optional example, the peripheral circuit is configured to: obtain flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and obtain the composite flip count difference according to the flip count differences respectively corresponding to the plurality of pairs of offset read voltages.

In an optional example, the peripheral circuit is configured to: perform a weighted operation on the flip count differences respectively corresponding to the plurality of pairs of offset read voltages to obtain the composite flip count difference.

In an optional example, in the weighted operation, a weight of the flip count difference is positively correlated with an offset value of the offset read voltage with respect to the candidate read voltage.

In an optional example, the flip count difference is a difference obtained by subtracting a second type of bit flip count from a first type of bit flip count; the first type of bit flip count is a number of bits whose values are different between the original data corresponding to a first offset voltage in a pair of offset read voltages and the original data corresponding to the candidate read voltage; and the second type of bit flip count is a number of bits whose values are different between the original data corresponding to a second offset voltage in the same pair of offset read voltages and the original data corresponding to the candidate read voltage.

In an optional example, the peripheral circuit is configured to: obtain a first mixed bit flip count according to respective bit flip counts of read voltages other than a third offset voltage in the plurality of pairs of offset read voltages; the third offset voltage is a voltage of the plurality of pairs of offset read voltages with a longest step size for an offset to a left side of the candidate read voltage; obtain a second mixed bit flip count according to respective bit flip counts of read voltages other than a fourth offset voltage in the plurality of pairs of offset read voltages; the fourth offset voltage is a voltage in the plurality of pairs of offset read voltages with a longest step size for an offset to a right side of the candidate read voltage; and obtain a difference between the mixed bit flip count and the second mixed bit flip count as the composite flip count difference.

In an optional example, the peripheral circuit is configured to: perform a weighted operation on respective bit flip counts of offset voltages other than the third offset voltage in the plurality of pairs of offset read voltages to obtain the first mixed bit flip count; and perform a weighted operation on respective bit flip counts of offset voltages other than the fourth offset voltage in the plurality of pairs of offset read voltages to obtain the second mixed bit flip count.

In an optional example, the peripheral circuit is further configured to: determine a current offset direction for adjusting the candidate read voltage and a current amount of offset for adjusting the candidate read voltage according to a sign of the composite flip count difference; and offset the candidate read voltage according to the current offset direction for adjusting the candidate read voltage and the current amount of offset for adjusting the candidate read voltage to obtain an adjusted candidate read voltage.

In an optional example, the peripheral circuit is configured to: determine the current offset direction for adjusting the candidate read voltage according to the sign of the composite flip count difference; and determine the current amount of offset for adjusting the candidate read voltage according to the current offset direction for adjusting the candidate read voltage and a last offset direction for adjusting the candidate read voltage.

In an optional example, the peripheral circuit is configured to: the current amount of offset for adjusting the candidate read voltage is determined as the last amount of offset for adjusting the candidate read voltage when the current offset direction for adjusting the candidate read voltage is the same as the last offset direction for adjusting the candidate read voltage; and the current amount of offset for adjusting the candidate read voltage is determined half of the last amount of offset for adjusting the candidate read voltage when the current offset direction for adjusting the candidate read voltage is different from the last offset direction for adjusting the candidate read voltage.

In an optional example, the peripheral circuit is configured to: offset the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

In an optional example, the peripheral circuit is further configured to: a read voltage of the memory device is determined as the candidate read voltage when the current amount of offset for adjusting the candidate read voltage is not greater than the offset threshold.

In an optional example, the peripheral circuit is further configured to: a read voltage of the memory device is determined as the candidate read voltage when the respective bit flip counts of the plurality of pairs of offset read voltages satisfy the specified condition.

In an optional example, the original data is obtained by reading the memory device in a single-level read SLR mode.

According to another aspect, a computer-readable storage medium storing an instruction therein is provided, the instruction, when executed on a controller in a memory system, implements the operating method of the memory system according to any one of the foregoing examples.

The technical solutions provided in the present disclosure may comprise the following beneficial effects:

The present disclosure provides a solution for searching the read voltage of the memory device in one or more rounds of iteration, where in each round of iteration process, in addition to reading the original data in the memory device by the current candidate read voltage, a plurality of pairs of offset read voltages on two sides of the candidate read voltage are determined, the offset values of two offset read voltages of each pair of offset read voltages with respect to the candidate read voltage are the same and the offset directions of two offset read voltages of each pair of offset read voltages with respect to the candidate read voltage are different, the original data in the memory device is read by the plurality of pairs of offset read voltages, then the original data corresponding to the candidate read voltage and the original data corresponding to the plurality of pairs of offset read voltages are combined, the adjustment manner of the candidate read voltage is integrated, for example, the original data corresponding to the candidate read voltage and the original data respectively corresponding to the plurality of pairs of offset read voltages are combined to comprehensively determine whether the error rate of the current candidate read voltage is at the lowest point, if not, the candidate read voltage is adjusted to enter the next round of iteration; in the solution, since it is required to refer to the original data corresponding to the current candidate read voltage and the plurality of voltages on the two sides of the current candidate read voltage to determine whether the error rate of the current candidate read voltage is at the lowest point, so that the error rate in the wider voltage range on the two sides of the current candidate read voltage can be considered, the noise interference is effectively reduced, the accuracy of the read voltage of the memory device is improved, and the accuracy of subsequent data reading is further ensured.

The above descriptions are merely examples of the present disclosure, and are not intended to limit the present disclosure, and any modifications, equivalent substitutions and improvements made within the spirit and principle of the present disclosure should be included in the protection scope of the present disclosure.

What is claimed is:

1. A method of operating a memory system, comprising:
performing a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and
adjusting the candidate read voltage based on the original data corresponding to the candidate read voltage and the original data respectively corresponding to each of the offset read voltages in the plurality of pairs of offset read voltages.

2. The method of claim 1, wherein the adjusting the candidate read voltage based on the original data corresponding to the candidate read voltage and the original data respectively corresponding to each of the offset read voltages in the plurality of pairs of offset read voltages comprises:
obtaining a bit flip count of the offset read voltage; the bit flip count is a number of bits whose values are different between the original data corresponding to the offset read voltage and the original data corresponding to the candidate read voltage; and
adjusting the candidate read voltage when the respective bit flip counts of the plurality of pairs of offset read voltages do not satisfy a specified condition.

3. The method of claim 2, wherein the adjusting the candidate read voltage when the respective bit flip counts of the plurality of pairs of offset read voltages do not satisfy the specified condition comprises:
obtaining a composite flip count difference according to the respective bit flip counts of the plurality of pairs of offset read voltages; and
adjusting the candidate read voltage when an absolute value of the composite flip count difference is not less than a difference threshold.

4. The method of claim 3, wherein the obtaining the composite flip count difference according to the respective bit flip counts of the plurality of pairs of offset read voltages comprises:
obtaining flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and
obtaining the composite flip count difference according to the flip count differences respectively corresponding to the plurality of pairs of offset read voltages.

5. The method of claim 4, wherein the obtaining the composite flip count difference according to the flip count differences respectively corresponding to the plurality of pairs of offset read voltages comprises:
performing a weighted operation on the flip count differences respectively corresponding to the plurality of pairs of offset read voltages to obtain the composite flip count difference.

6. The method of claim 4, wherein the flip count difference is a difference obtained by subtracting a second type of bit flip count from a first type of bit flip count;
the first type of bit flip count is a number of bits whose values are different between an original data corresponding to a first offset voltage in a pair of offset read voltages and the original data corresponding to the candidate read voltage; and the second type of bit flip count is a number of bits whose values are different between an original data corresponding to a second offset voltage in the same pair of offset read voltages and the original data corresponding to the candidate read voltage.

7. The method of claim 3, wherein the obtaining the composite flip count difference according to the respective bit flip counts of the plurality of pairs of offset read voltages comprises:
obtaining a first mixed bit flip count according to respective bit flip counts of voltages other than a third offset voltage in the plurality of pairs of offset read voltages; the third offset voltage is a voltage of the plurality of pairs of offset read voltages with a longest step size for an offset to a left side of the candidate read voltage;
obtaining a second mixed bit flip count according to respective bit flip counts of voltages other than a fourth offset voltage in the plurality of pairs of offset read voltages; the fourth offset voltage is a voltage in the plurality of pairs of offset read voltages with a longest step size for an offset to a right side of the candidate read voltage; and
determining a difference between the mixed bit flip count and the second mixed bit flip count as the composite flip count difference.

8. The method of claim 3, wherein the adjusting the candidate read voltage comprises:
determining an offset direction for adjusting the candidate read voltage and an amount of offset for adjusting the candidate read voltage according to a sign of the composite flip count difference; and
offsetting the candidate read voltage according to a current offset direction for adjusting the candidate read voltage and a current amount of offset for adjusting the candidate read voltage to obtain an adjusted candidate read voltage.

9. The method of claim 8, wherein the determining the current offset direction for adjusting the candidate read voltage and the current amount of offset for adjusting the candidate read voltage according to the sign of the composite flip count difference comprises:
determining the current offset direction for adjusting the candidate read voltage according to the sign of the composite flip count difference; and
determining the current amount of offset for adjusting the candidate read voltage according to the current offset direction for adjusting the candidate read voltage and a last offset direction for updating the candidate read voltage.

10. The method of claim 8, wherein the offsetting the candidate read voltage according to the current offset direction for adjusting the candidate read voltage and the current amount of offset for adjusting the candidate read voltage to obtain an adjusted candidate read voltage comprises:
offsetting the candidate read voltage according to the current offset direction for adjusting the candidate read voltage and the current amount of offset for adjusting the candidate read voltage to obtain the adjusted candidate read voltage when the current amount of offset for adjusting the candidate read voltage is greater than an offset threshold.

11. The method of claim 1, wherein the original data is obtained by reading the memory device in a single-level read SLR mode.

12. A memory system, comprising:
a memory device; and
a controller;
the controller is configured to:
perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and
adjust the candidate read voltage based on the original data corresponding to the candidate read voltage and the original data respectively corresponding to each of the offset read voltages in the plurality of pairs of offset read voltages.

13. The memory system of claim 12, wherein the controller is configured to:
obtain a bit flip count of the offset read voltage; the bit flip count is a number of bits whose values are different between the original data corresponding to the offset read voltage and the original data corresponding to the candidate read voltage; and
adjust the candidate read voltage when the respective bit flip counts of the plurality of pairs of offset read voltages do not satisfy a specified condition.

14. The memory system of claim 13, wherein the controller is configured to:
obtain a composite flip count difference according to the respective bit flip counts of the plurality of pairs of offset read voltages; and
adjust the candidate read voltage when an absolute value of the composite flip count difference is not less than a difference threshold.

15. The memory system of claim 14, wherein the controller is configured to:
obtain flip count differences respectively corresponding to the plurality of pairs of offset read voltages according to the respective bit flip counts of the plurality of pairs of offset read voltages; the flip count differences are differences calculated according to bit flip counts of a same pair of offset read voltages; and
obtain the composite flip count difference according to the flip count differences respectively corresponding to the plurality of pairs of offset read voltages.

16. The memory system of claim 15, wherein the controller is configured to:
perform a weighted operation on the flip count differences respectively corresponding to the plurality of pairs of offset read voltages to obtain the composite flip count difference.

17. The memory system of claim 15, wherein the flip count difference is a difference obtained by subtracting a second type of bit flip count from a first type of bit flip count;
the first type of bit flip count is a number of bits whose values are different between an original data corresponding to a first offset voltage in a pair of offset read voltages and the original data corresponding to the candidate read voltage; and the second type of bit flip count is a number of bits whose values are different between an original data corresponding to a second offset voltage in the same pair of offset read voltages and the original data corresponding to the candidate read voltage.

18. The memory system of claim 14, wherein the controller is configured to:
obtain a first mixed bit flip count according to respective bit flip counts of read voltages other than a third offset voltage in the plurality of pairs of offset read voltages; the third offset voltage is a voltage of the plurality of pairs of offset read voltages with a longest step size for an offset to a left side of the candidate read voltage;
obtain a second mixed bit flip count according to respective bit flip counts of read voltages other than a fourth offset voltage in the plurality of pairs of offset read voltages; the fourth offset voltage is a voltage in the plurality of pairs of offset read voltages with a longest step size offset to a right side of the candidate read voltage; and
obtain a difference between the mixed bit flip count and the second mixed bit flip count as the composite flip count difference.

19. The memory system of claim 14, wherein the controller is further configured to:
determine a current offset direction for adjusting the candidate read voltage and a current amount of offset for adjusting the candidate read voltage according to a sign of the composite flip count difference; and
offset the candidate read voltage according to the current offset direction for adjusting the candidate read voltage and the current amount of offset for adjusting the candidate read voltage to obtain an adjusted candidate read voltage.

20. A memory device, comprising:
a memory cell array; and
a peripheral circuit;
the peripheral circuit is configured to:
perform a read operation using a candidate read voltage and a plurality of pairs of offset read voltages respectively, to obtain an original data corresponding to the candidate read voltage and an original data respectively corresponding to each of the offset read voltages in the plurality of pairs of offset read voltages; each pair of the plurality of pairs of offset read voltages are two voltages obtained by respectively offsetting to two sides of the candidate read voltage by a same step size, and step sizes of an offset of different pairs of offset read voltages with respect to the candidate read voltage are different; and
adjust the candidate read voltage based on the original data corresponding to the candidate read voltage and the original data respectively corresponding to each of the offset read voltages in the plurality of pairs of offset read voltages.
